(19) United States
(12) Patent Application Publication
(10) Pub. No.: US 2026/0293462 A1
(43) Pub. Date: Sep. 24, 2026

(54) DISPLAY PANEL AND METHOD FOR MANUFACTURING THE SAME, AND DISPLAY APPARATUS

(71) Applicants: Chengdu BOE Optoelectronics Technology Co., Ltd., Chengdu, Sichuan (CN); BOE TECHNOLOGY GROUP CO., LTD., Beijing (CN)

(72) Inventors: Huihui LI, Beijing (CN); Rongjian YAN, Beijing (CN); Ganghu LIU, Beijing (CN); Yu LIU, Beijing (CN); Hao LI, Beijing (CN); Zhenyan SHI, Beijing (CN); Yahui ZHANG, Beijing (CN)

(73) Assignees: Chengdu BOE Optoelectronics Technology Co., Ltd., Chengdu, Sichuan (CN); BOE TECHNOLOGY GROUP CO., LTD., Beijing (CN)

(21) Appl. No.: 19/475,431

(22) PCT Filed: Oct. 22, 2024
(86) PCT No.: PCT/CN2024/126542

§ 371 Date: Oct. 15, 2025

(30) Foreign Application Priority Data
Nov. 20, 2023 (CN) 202311553591.0

(51) Int. Cl. H10K 59/131

(52) U.S. Cl. CPC H10K 59/131

(57) ABSTRACT

A display panel includes: a substrate, a first source-drain conductive layer, a first insulating layer, and a light-emitting device layer. The first source-drain conductive layer includes first connection lines, second connection lines and third connection lines. The light-emitting device layer includes a first electrode layer, a light-emitting functional layer, and a second electrode layer. The light-emitting device layer forms first light-emitting devices, second light-emitting devices, and third light-emitting devices. The first electrode layer includes first electrodes of the first light-emitting devices, second electrodes of the second light-emitting devices, and third electrodes of the third light-emitting devices. In a direction perpendicular to the substrate, at least two of a distance between the first electrode and the first connection line, a distance between the second electrode and the second connection line, and a distance between the third electrode and the third connection line are not equal.

### CROSS-REFERENCE TO RELATED APPLICATIONS

This application is a national phase entry under 35 USC 371 of International Patent Application No. PCT/CN2024/126542, filed on Oct. 22, 2024, which claims priority to Chinese Patent Application No. 202311553591.0, filed on Nov. 20, 2023, which are incorporated herein by reference in their entirety.

### TECHNICAL FIELD

The present disclosure relates to the field of display technologies, and in particular, to a display panel and a method for manufacturing the same, and a display apparatus.

### BACKGROUND

Organic light-emitting diodes (OLEDs) have been widely used in the display field due to advantages such as self-luminous, low driving voltage, high light-emitting efficiency, high response speed, and flexible display.

### SUMMARY

In an aspect, a display panel is provided. The display panel includes: a substrate, a first source-drain conductive layer, a first insulating layer, and a light-emitting device layer. The first source-drain conductive layer is located on a side of the substrate. The first source-drain conductive layer includes first connection lines, second connection lines and third connection lines. The first insulating layer is located on a side of the first source-drain conductive layer away from the substrate. The light-emitting device layer is located on a side of the first insulating layer away from the substrate. The light-emitting device layer includes a first electrode layer, a light-emitting functional layer, and a second electrode layer that are sequentially stacked in a direction away from the substrate; the light-emitting device layer forms first light-emitting devices, second light-emitting devices, and third light-emitting devices, which emit light of different colors; the first electrode layer includes first electrodes belonging to the first light-emitting devices, second electrodes belonging to the second light-emitting devices, and third electrodes belonging to the third light-emitting devices; orthographic projections, on the substrate, of a first electrode and a first connection line overlap; orthographic projections, on the substrate, of a second electrode and a second connection line overlap; and orthographic projections, on the substrate, of a third electrode and a third connection line overlap. In a direction perpendicular to the substrate, at least two of a distance between the first electrode and the first connection line, a distance between the second electrode and the second connection line, and a distance between the third electrode and the third connection line are not equal, so that a difference between any two of a parasitic capacitance created by the first electrode and the first connection line, a parasitic capacitance created by the second electrode and the second connection line, and a parasitic capacitance created by the third electrode and the third connection line is within a preset range.

In some embodiments, a distance between one electrode, among the first electrode, the second electrode and the third electrode, and a connection line whose orthographic projection on the substrate overlaps with an orthographic projection of the one electrode on the substrate is greater than a distance between each of remaining two electrodes, among the first electrode, the second electrode and the third electrode, and a connection line whose orthographic projection on the substrate overlaps with an orthographic projection of the each of remaining two electrodes on the substrate.

In some embodiments, the first insulating layer includes a first insulating portion, a second insulating portion, and a third insulating portion. The first insulating portion is disposed between the first electrode and the first connection line, the second insulating portion is disposed between the second electrode and the second connection line, and the third insulating portion is disposed between the third electrode and the third connection line. One of a thickness of the first insulating portion, a thickness of the second insulating portion and a thickness of the third insulating portion is greater than remaining two of the thickness of the first insulating portion, the thickness of the second insulating portion and the thickness of the third insulating portion.

In some embodiments, a surface, away from the substrate, of one of the first insulating portion, the second insulating portion and the third insulating portion is higher than surfaces, away from the substrate, of remaining two of the first insulating portion, the second insulating portion and the third insulating portion.

In some embodiments, a thickness of the first connection line, a thickness of the second connection line, and a thickness of the third connection line are equal.

In some embodiments, a thickness of one of the first connection line, the second connection line and the third connection line is less than thicknesses of remaining two of the first connection line, the second connection line and the third connection line.

In some embodiments, surfaces, away from the substrate, of the first insulating portion, the second insulating portion and the third insulating portion are flush with each other.

In some embodiments, the first insulating portion, the second insulating portion and the third insulating portion are in a one-piece structure.

In some embodiments, among the distance between the first electrode and the first connection line, the distance between the second electrode and the second connection line, and the distance between the third electrode and the third connection line, a maximum distance is dₘₐₓ, and remaining two distances are dₒ₁ and dₒ₂, where dₘₐₓ/dₒ₁ is less than or equal to 1.3, and/or dₘₐₓ/dₒ₂ is less than or equal to 1.3.

In another aspect, a display panel includes a substrate, a first source-drain conductive layer, a light-emitting device layer and a first insulating layer. The first source-drain conductive layer is located on a side of the substrate, and the first source-drain conductive layer includes first connection lines, second connection lines and third connection lines. The light-emitting device layer is located on a side of the first source-drain conductive layer away from the substrate. The light-emitting device layer includes a first electrode layer, a light-emitting functional layer, and a second electrode layer that are sequentially stacked in a direction away from the substrate; the light-emitting device layer forms first light-emitting devices, second light-emitting devices, and third light-emitting devices, which emit light of different colors; the first electrode layer includes first electrodes belonging to the first light-emitting devices, second electrodes belonging to the second light-emitting devices, and third electrodes belonging to the third light-emitting devices; orthographic projections, on the substrate, of a first electrode and a first connection line overlap; orthographic projections, on the substrate, of a second electrode and a second connection line overlap; and orthographic projections, on the substrate, of a third electrode and a third connection line overlap. The first insulating layer is located between the first source-drain conductive layer and the first electrode layer. The first insulating layer includes a first insulating portion, a second insulating portion, and a third insulating portion. The first insulating portion is disposed between the first electrode and the first connection line, the second insulating portion is disposed between the second electrode and the second connection line, and the third insulating portion is disposed between the third electrode and the third connection line. At least two of a dielectric constant of the first insulating portion, a dielectric constant of the second insulating portion and a dielectric constant of the third insulating portion are not equal, so that a difference between any two of a parasitic capacitance created by the first electrode and the first connection line, a parasitic capacitance created by the second electrode and the second connection line, and a parasitic capacitance created by the third electrode and the third connection line is within a preset range.

In some embodiments, one of the dielectric constant of the first insulating portion, the dielectric constant of the second insulating portion and the dielectric constant of the third insulating portion is less than remaining two of the dielectric constant of the first insulating portion, the dielectric constant of the second insulating portion and the dielectric constant of the third insulating portion.

In some embodiments, dielectric constants of two insulating portions with relatively larger dielectric constants among the first insulating portion, the second insulating portion and the third insulating portion are the same, and the two insulating portions with relatively larger dielectric constants are in a one-piece structure; and one insulating portion with a minimum dielectric constant among the first insulating portion, the second insulating portion and the third insulating portion is embedded in the one-piece structure formed by the two insulating portions with relatively larger dielectric constants.

In some embodiments, among the dielectric constant of the first insulating portion, the dielectric constant of the second insulating portion and the dielectric constant of the third insulating portion, a minimum dielectric constant is εₘₐₓ, and remaining two dielectric constants are εₒ₁ and εₒ₂, where εₘₐₓ/εₒ₁ is greater than or equal to 0.7, and/or εₘₐₓ/εₒ₂ is greater than or equal to 0.7.

In yet another aspect, a display panel includes a substrate, a first source-drain conductive layer, a first insulating layer and a light-emitting device layer. The first source-drain conductive layer is located on a side of the substrate, and the first source-drain conductive layer includes first connection lines, second connection lines and third connection lines. The first insulating layer is located on a side of the first source-drain conductive layer away from the substrate. The light-emitting device layer is located on a side of the first insulating layer away from the substrate. The light-emitting device layer includes a first electrode layer, a light-emitting functional layer, and a second electrode layer that are sequentially stacked in a direction away from the substrate; the light-emitting device layer forms a plurality of first light-emitting devices, a plurality of second light-emitting devices, and a plurality of third light-emitting devices, which emit light of different colors; the first electrode layer includes first electrodes belonging to the plurality of first light-emitting devices, second electrodes belonging to the plurality of second light-emitting devices, and third electrodes belonging to the plurality of third light-emitting devices; orthographic projections, on the substrate, of a first electrode and a first connection segment of a first connection line overlap; orthographic projections, on the substrate, of a second electrode and a second connection segment of a second connection line overlap; and orthographic projections, on the substrate, of a third electrode and a third connection segment of a third connection line overlap. At least two of a width of the first connection segment, a width of the second connection segment, and a width of the third connection segment are not equal, so that a difference between any two of a parasitic capacitance created by the first electrode and the first connection line, a parasitic capacitance created by the second electrode and the second connection line, and a parasitic capacitance created by the third electrode and the third connection line is within a preset range.

In some embodiments, one of the width of the first connection segment, the width of the second connection segment, and the width of the third connection segment is less than remaining two of the width of the first connection segment, the width of the second connection segment, and the width of the third connection segment.

In some embodiments, a portion of the first connection line, whose orthographic projection on the substrate does not overlap with an orthographic projection of the first electrode on the substrate, is a fourth connection segment; a portion of the second connection line, whose orthographic projection on the substrate does not overlap with an orthographic projection of the second electrode on the substrate, is a fifth connection segment; and a portion of the third connection line, whose orthographic projection on the substrate does not overlap with an orthographic projection of the third electrode on the substrate, is a sixth connection segment. A width of the fourth connection segment is greater than the width of the first connection segment; and/or a width of the fifth connection segment is greater than the width of the second connection segment; and/or a width of the sixth connection segment is greater than the width of the third connection segment.

In some embodiments, the plurality of first light-emitting devices, the plurality of second light-emitting devices, and the plurality of third light-emitting devices are arranged in a plurality of rows in a first direction, and are arranged in a plurality of columns in a second direction. Each row of light-emitting devices includes first light-emitting devices and third light-emitting devices arranged alternately in the first direction, or each row of light-emitting devices includes second light-emitting devices arranged in the first direction. A light-emitting device row consisting of first light-emitting devices and third light-emitting devices and a light-emitting device row consisting of second light-emitting devices are arranged alternately. Each column of light-emitting devices includes second light-emitting devices and third light-emitting devices arranged alternately in the second direction, or each column of light-emitting devices includes first light-emitting devices arranged in the second direction. A light-emitting device column consisting of second light-emitting devices and third light-emitting devices and a light-emitting device column consisting of first light-emitting devices are arranged alternately. The second connection line is also used as the third connection line, and the second connection segment and the third connection segment are different portions of the second connection line.

In yet another aspect, a display apparatus is provided. The display apparatus includes the display panel as described in any one of the above embodiments.

In yet another aspect, a method for manufacturing a display panel is provided, which is applied to the display panel described in any one of the above embodiments. The method includes: forming a first source-drain conductive layer on a substrate, the first source-drain conductive layer including first connection lines, second connection lines and third connection lines; forming a first insulating layer on a side of the first source-drain conductive layer away from the substrate using a half-tone mask; and forming a light-emitting device layer on a side of the first insulating layer away from the substrate. The light-emitting device layer includes a first electrode layer, a light-emitting functional layer, and a second electrode layer that are sequentially stacked in a direction away from the substrate. The light-emitting device layer forms first light-emitting devices, second light-emitting devices, and third light-emitting devices, which emit light of different colors. The first electrode layer includes first electrodes belonging to the first light-emitting devices, second electrodes belonging to the second light-emitting devices, and third electrodes belonging to the third light-emitting devices. Orthographic projections, on the substrate, of a first electrode and a first connection line overlap; orthographic projections, on the substrate, of a second electrode and a second connection line overlap; and orthographic projections, on the substrate, of a third electrode and a third connection line overlap. At least two of a thickness of a portion of the first insulating layer between the first electrode and the first connection line, a thickness of a portion of the first insulating layer between the second electrode and the second connection line, and a thickness of a portion of the first insulating layer between the third electrode and the third connection line are not equal.

In yet another aspect, a method for manufacturing a display panel is provided, which is applied to the display panel described in any one of the above embodiments. The method includes: forming a first source-drain conductive layer on a substrate, the first source-drain conductive layer including first connection lines, second connection lines and third connection lines; forming a first insulating layer on a side of the first source-drain conductive layer away from the substrate; and
forming a light-emitting device layer on a side of the first insulating layer away from the substrate. The light-emitting device layer includes a first electrode layer, a light-emitting functional layer, and a second electrode layer that are sequentially stacked in a direction away from the substrate. The light-emitting device layer forms first light-emitting devices, second light-emitting devices, and third light-emitting devices, which emit light of different colors. The first electrode layer includes first electrodes belonging to the first light-emitting devices, second electrodes belonging to the second light-emitting devices, and third electrodes belonging to the third light-emitting devices. Orthographic projections, on the substrate, of a first electrode and a first connection line overlap; orthographic projections, on the substrate, of a second electrode and a second connection line overlap; and orthographic projections, on the substrate, of a third electrode and a third connection line overlap. The first insulating layer includes a first insulating portion, a second insulating portion, and a third insulating portion. The first insulating portion is disposed between the first electrode and the first connection line, the second insulating portion is disposed between the second electrode and the second connection line, and the third insulating portion is disposed between the third electrode and the third connection line. At least two of a dielectric constant of the first insulating portion, a dielectric constant of the second insulating portion and a dielectric constant of the third insulating portion are not equal.

### BRIEF DESCRIPTION OF THE DRAWINGS

In order to describe technical solutions in some embodiments of the present disclosure more clearly, the accompanying drawings to be used in some embodiments of the present disclosure will be introduced briefly. However, the accompanying drawings to be described below are merely some embodiments of the present disclosure, and a person of ordinary skill in the art can obtain other drawings according to those drawings. In addition, the accompanying drawings in the following description may be regarded as schematic diagrams, but are not limitations on actual sizes of products, actual processes of methods and actual timings of signals involved in the embodiments of the present disclosure.

FIG. 1 is a structural diagram of a display apparatus, in accordance with some embodiments;

FIG. 2 is a structural diagram of a display panel, in accordance with some embodiments;

FIG. 3 is a sectional view taken along the section line A-A in FIG. 2;

FIG. 4 is another sectional view taken along the section line A-A in FIG. 2;

FIG. 5 is a structural diagram of a pixel circuit, in accordance with some embodiments;

FIG. 6 is a partial enlarged view of the region B in FIG. 2;

FIG. 7 is another partial enlarged view of the region B in FIG. 2;

FIG. 8 is a partial enlarged view of the region B in FIG. 2;

FIG. 9 is another partial enlarged view of the region B in FIG. 2;

FIG. 10 is a diagram showing a structure in which a first insulating portion protrudes from a second insulating portion and a third insulating portion, in accordance with some embodiments;

FIG. 11 is a diagram showing a structure in which a second insulating portion protrudes from a third insulating portion and a first insulating portion, in accordance with some embodiments;

FIG. 12 is a diagram showing a structure in which a third insulating portion protrudes from a first insulating portion and a second insulating portion, in accordance with some embodiments;

FIG. 13 is a diagram showing a structure in which a thickness of a first connection line is minimum, in accordance with some embodiments;

FIG. 14 is a diagram showing a structure in which a thickness of a second connection line is minimum, in accordance with some embodiments;

FIG. 15 is a diagram showing a structure in which a thickness of a third connection line is minimum, in accordance with some embodiments;

FIG. 16 is a diagram showing a structure in which a first insulating portion is embedded in a one-piece structure composed of a second insulating portion and a third insulating portion, in accordance with some embodiments;

FIG. 17 is a diagram showing a structure in which a second insulating portion is embedded in a one-piece structure composed of a first insulating portion and a third insulating portion, in accordance with some embodiments;

FIG. 18 is a diagram showing a structure in which a third insulating portion is embedded in a one-piece structure composed of a first insulating portion and a second insulating portion, in accordance with some embodiments;

FIG. 19 is a diagram showing a structure in which a width of a first connection segment is minimum, in accordance with some embodiments;

FIG. 20 is a diagram showing a structure in which a width of a second connection segment is minimum, in accordance with some embodiments;

FIG. 21 is a diagram showing a structure in which a width of a third connection segment is minimum, in accordance with some embodiments; and

FIGS. 22 and 23 are each a flow diagram of a method for manufacturing a display panel, in accordance with some embodiments.

### DETAILED DESCRIPTION

The technical solutions in some embodiments of the present disclosure will be described clearly and completely with reference to the accompanying drawings. However, the described embodiments are merely some but not all embodiments of the present disclosure. All other embodiments obtained by a person of ordinary skill in the art based on embodiments of the present disclosure shall be included in the protection scope of the present disclosure.

Unless the context requires otherwise, throughout the specification and the claims, the term “comprise” and other forms thereof such as the third-person singular form “comprises” and the present participle form “comprising” are construed as an open and inclusive meaning, i.e., “including, but not limited to”. In the description of the specification, the terms such as “one embodiment,” “some embodiments,” “exemplary embodiments,” “example,” “specific example,” or “some examples” are intended to indicate that specific features, structures, materials, or characteristics related to the embodiment(s) or example(s) are included in at least one embodiment or example of the present disclosure. Schematic representations of the above terms do not necessarily refer to the same embodiment(s) or example(s). In addition, the specific features, structures, materials, or characteristics may be included in any one or more embodiments or examples in any suitable manner.

Hereinafter, terms “first” and “second” are used for descriptive purposes only, and are not to be construed as indicating or implying a relative importance or implicitly indicating the number of indicated technical features. Thus, features defined with “first” or “second” may explicitly or implicitly include one or more of the features. In the description of the embodiments of the present disclosure, the term “multiple”, “a plurality of” or “the plurality of” means two or more unless otherwise specified.

In the description of some embodiments, the term “connected” and derivatives thereof may be used. For example, the term “connected” may be used in the description of some embodiments to indicate that two or more components are in direct physical or electrical contact with each other. The embodiments disclosed herein are not necessarily limited to the content herein.

The phrase “at least one of A, B, and C” has the same meaning as the phrase “at least one of A, B, or C”, both including the following combinations of A, B, and C: only A, only B, only C, a combination of A and B, a combination of A and C, a combination of B and C, and a combination of A, B, and C.

The phrase “A and/or B” includes the following three combinations: only A, only B, and a combination of A and B.

The term such as “substantially” or “approximately” as used herein includes a stated value and an average value within an acceptable range of deviation of a particular value determined by a person of ordinary skill in the art, considering measurement in question and errors associated with measurement of a particular quantity (i.e., limitations of a measurement system).

The term such as “parallel”, “perpendicular”, or “equal” as used herein includes a stated condition and a condition similar to the stated condition. A range of the similar condition is within an acceptable deviation range, and the acceptable deviation range is determined by a person of ordinary skill in the art, considering measurement in question and errors associated with measurement of a particular quantity (i.e., the limitations of a measurement system). For example, the term “parallel” includes absolute parallelism and approximate parallelism, and an acceptable range of deviation of the approximate parallelism may be, for example, a deviation within 5°; the term “perpendicular” includes absolute perpendicularity and approximate perpendicularity, and an acceptable range of deviation of the approximate perpendicularity may also be, for example, a deviation within 5°; and the term “equal” includes absolute equality and approximate equality, and an acceptable range of deviation of the approximate equality may be that, for example, a difference between the two that are equal is less than or equal to 5% of either of the two.

It will be understood that, when a layer or element is referred to as being on another layer or substrate, it may be that the layer or element is directly on the another layer or substrate, or it may be that intermediate layer(s) exist between the layer or element and the another layer or substrate.

Exemplary embodiments are described herein with reference to sectional views and/or plan views that are schematic illustrations of idealized embodiments. In the drawings, thicknesses of layers and areas of regions are enlarged for clarity. Variations in shape with respect to the accompanying drawings due to, for example, manufacturing technologies and/or tolerances may be envisaged. Therefore, the exemplary embodiments should not be construed as being limited to the shapes of the regions shown herein, but including shape deviations due to, for example, manufacturing. For example, an etched region shown to have a rectangular shape generally has a feature of being curved. Thus, the regions shown in the accompanying drawings are schematic in nature, and their shapes are not intended to show actual shapes of the regions in a device, and are not intended to limit the scope of the exemplary embodiments.

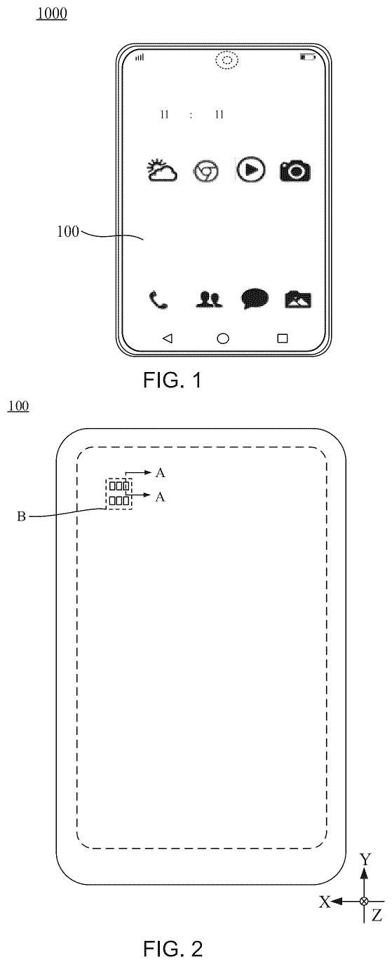

Some embodiments of the present disclosure provide a display apparatus 1000, and as shown in FIG. 1, the display apparatus 1000 may be any apparatus that displays images whether in motion (e.g., videos) or stationary (e.g., still images), and whether textual or graphical. For example, the display apparatus 1000 may be any product or component having a display function, such as a television, a notebook computer, a tablet computer, a cell phone, a personal digital assistant (PDA), a navigator, a wearable device, an augmented reality (AR) device, a virtual reality (VR) device, or the like.

The display apparatus 1000 may be a liquid crystal display (LCD) apparatus, an organic light-emitting diode (OLED) display apparatus, a quantum dot light-emitting diode (QLED) display apparatus, a mini/micro light-emitting diode (MLED) display apparatus, or an active-matrix organic light-emitting diode (AMOLED) display apparatus. The embodiments of the present disclosure are described by taking an example in which the display apparatus is an OLED display apparatus.

AMOLED display apparatuses have characteristics of high response speed, high contrast, wide viewing angle and low power consumption, and are one of the hot research topics in the field of display technology today. The following embodiments are described by taking an example in which the display apparatus 1000 is an AMOLED display apparatus.

As shown in FIG. 1, the display apparatus 1000 includes a display panel 100. As shown in FIGS. 2 to 4, the display panel 100 includes a substrate 10, a pixel circuit stack layer 20, and a light-emitting device layer 30.

The substrate 10 may be a flexible substrate 10 or a rigid substrate 10. A material of the substrate 10 may include polymer resin or glass. For example, the substrate 10 may be flexible, and the material of the substrate 10 includes polymer resin, such as one of polyethersulfone (PES), polyarylate (PAR), polyetherimide (PEI), polyethylene naphthalate (PEN), polyethylene terephthalate (PET), polyphenylene sulfide (PPS), polyimide (PI), polycarbonate (PC), and cellulose acetate propionate (CAP). For example, the substrate 10 may be rigid, and the material of the substrate 10 includes a glass material containing SiO₂ as a main component.

It will be noted that the substrate 10 may be of a single-layer structure or a multi-layer structure. For example, in a case where the substrate 10 is of a multi-layer structure, the substrate 10 may include a base and a buffer layer disposed on the base. A material of the buffer layer may include an inorganic insulating material, such as silicon nitride (SiNx, x>0), silicon oxynitride (SiON), and silicon oxide (SiOx, x>0). The buffer layer is used to provide a good foundation for forming a thin film when the thin film is fabricated on the substrate 10.

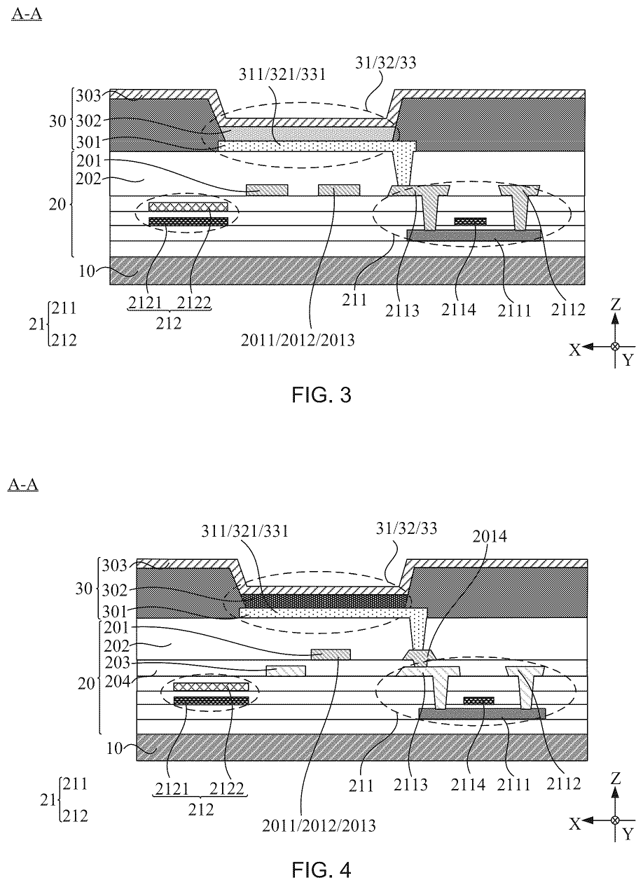

As shown in FIGS. 3 and 4, the pixel circuit stack layer 20 is disposed on the substrate 10, and the pixel circuit stack layer 20 includes pixel circuits 21. The pixel circuit 21 includes a plurality of thin-film transistors (abbreviated as TFTs) 211 and at least one storage capacitor (abbreviated as C) 212. The thin-film transistors 211 are, for example, oxide thin-film transistors. The oxide thin-film transistor has high carrier mobility, thereby improving the response speed of the thin-film transistor 211.

As shown in FIGS. 3 and 4, the thin-film transistor 211 include an active layer 2111, a source 2112, a drain 2113 and a gate 2114, and the source 2112 and the drain 2113 are in contact with the active layer 2111. It will be noted that the source 2112 and the drain 2113 can be interchanged. The storage capacitor 212 includes a first plate 2121 and a second plate 2122 that are arranged opposite to each other.

A structure of the pixel circuit 21 varies, which may be set according to actual needs. For example, the structure of the pixel circuit 21 may include a structure of “2T1C”, “3T1C”, “6T1C”, “7T1C”, “6T2C”, or “7T2C”, where “T” represents a thin-film transistor 211, a number before “T” represents the number of thin-film transistors 211, “C” represents a storage capacitor 212, and a number before “C” represents the number of storage capacitors 212.

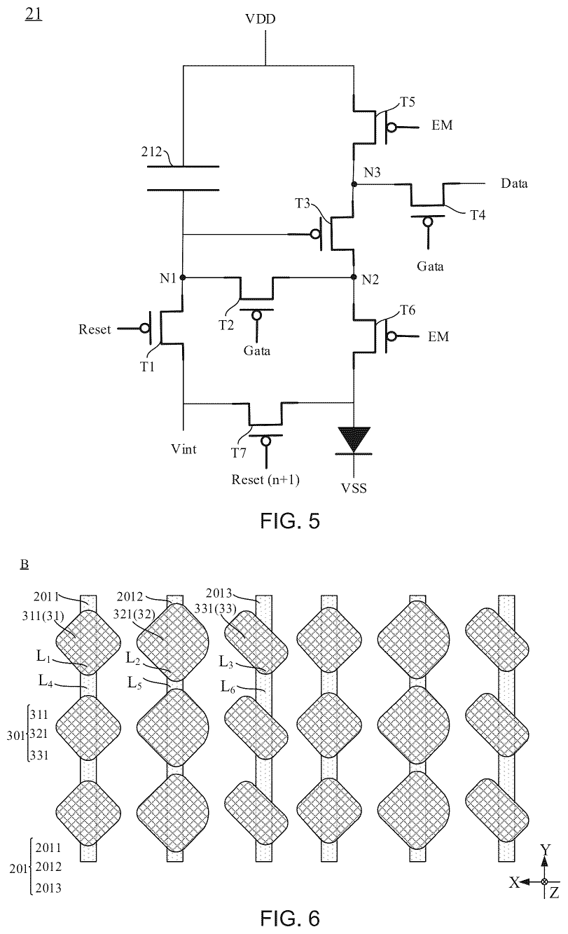

For example, as shown in FIG. 5, the structure of the pixel circuit 21 is a structure of 7T1C. The pixel circuit 21 includes a first reset transistor T1, a compensation transistor T2, a driving transistor T3, a writing transistor T4, a first light-emitting control transistor T5, a second light-emitting control transistor T6, a second reset transistor T7, and a storage capacitor 212. A control electrode of the first reset transistor T1 is electrically connected to a first reset signal terminal Reset, a first electrode of the first reset transistor T1 is electrically connected to an initialization signal terminal Vinit, and a second electrode of the first reset transistor T1 is electrically connected to a first node N1. A control electrode of the compensation transistor T2 is electrically connected to a scan signal terminal Gate, a first electrode of the compensation transistor T2 is electrically connected to a second node N2, and a second electrode of the compensation transistor T2 is electrically connected to the first node N1. A control electrode of the driving transistor T3 is electrically connected to the first node N1, a first electrode of the driving transistor T3 is electrically connected to a third node N3, and a second electrode of the driving transistor T3 is electrically connected to the second node N2. A control electrode of the writing transistor T4 is electrically connected to the scan signal terminal Gate, a first electrode of the writing transistor T4 is electrically connected to a data signal terminal Data, and a second electrode of the writing transistor T4 is electrically connected to the third node N3. A control electrode of the first light-emitting control transistor T5 is electrically connected to an enable signal terminal EM, a first electrode of the first light-emitting control transistor T5 is electrically connected to a first power voltage terminal VDD, and a second electrode of the first light-emitting control transistor T5 is electrically connected to the third node N3. A control electrode of the second light-emitting control transistor T6 is electrically connected to the enable signal terminal EM, a first electrode of the second light-emitting control transistor T6 is electrically connected to the second node N2, and a second electrode of the second light-emitting control transistor T6 is electrically connected to an anode of a light-emitting device. A control electrode of the second reset transistor T7 is electrically connected to a second reset signal terminal Reset(n+1), a first electrode of the second reset transistor T7 is electrically connected to the initialization signal terminal Vinit, and a second electrode of the second reset transistor T7 is electrically connected to the anode of the light-emitting device. A second plate of the storage capacitor 212 is electrically connected to the first power voltage terminal VDD, and a first plate of the storage capacitor 212 is electrically connected to the first node N1. A cathode of the light-emitting device is electrically connected to a second power voltage terminal VSS.

A first electrode of a thin-film transistor 211 may be a source, and a second electrode of the thin-film transistor 211 may be a drain; alternatively, the first electrode may be the drain, and the second electrode may be the source, which will not be limited in the embodiments of the present disclosure. The first node N1, the second node N2 and the third node N3 do not represent actual existing components, but represent junctions of related electrical connections of sub-circuits or electronic components in a circuit diagram. That is, these nodes are equivalent to junctions of related electrical connections of sub-circuits or electronic components in the circuit diagram. Furthermore, “VDD” in the first power voltage terminal VDD is a constant high potential signal, and the embodiments of the present disclosure do not limit the voltage signal to a constant high potential signal such as VDD or VGH. Similarly, “VSS” in the second power voltage terminal VSS is a constant low potential signal, and the embodiments of the present disclosure do not limit the voltage signal to a constant low potential signal such as VSS, Vinit or VGL.

It will be noted that, according to the on-off type, the thin-film transistors 211 include P-type thin-film transistors and N-type thin-film transistors. The thin-film transistors 211 provided in the embodiments of the present disclosure are not limited to this, and they may be P-type thin-film transistors or N-type thin-film transistors, which are determined according to specific implementations. According to the film layer structure type, the thin-film transistors 211 include bottom-gate thin-film transistors and top-gate thin-film transistors. The thin-film transistors 211 provided in the embodiments of the present disclosure are not limited to this. In the following embodiments, the top-gate thin-film transistors are taken as an example.

As shown in FIGS. 3 and 4, the light-emitting device layer 30 is located on a side of the pixel circuit stack layer 20 away from the substrate 10. As shown in FIGS. 6 to 9, the light-emitting device layer 30 forms first light-emitting devices 31, second light-emitting devices 32, and third light-emitting devices 33, which emit light of different colors. A color of light emitted by the first light-emitting devices 31, a color of light emitted by the second light-emitting devices 32, and a color of light emitted by the third light-emitting devices 33 are three primary colors. For example, the color of light emitted by the first light-emitting devices 31 is red, the color of light emitted by the second light-emitting devices 32 is blue, and the color of light emitted by the third light-emitting devices 33 is green.

As shown in FIGS. 3 and 4, the light-emitting device layer 30 includes a first electrode layer 301, a light-emitting functional layer 302, and a second electrode layer 303 that are sequentially stacked in a direction away from the substrate 10.

The light-emitting functional layer 302 may include only a light-emitting layer; or in addition to the light-emitting layer, the light-emitting functional layer 22 further includes at least one of an electron transport layer (ETL), an electron injection layer (EIL), a hole transport layer (HTL) or a hole injection layer (HIL).

It will be noted that the first electrode layer 301 is an anode layer, and the second electrode layer 303 is a cathode layer; alternatively, the first electrode layer 301 is the cathode layer, and the second electrode layer 303 is the anode layer. The embodiments of the present disclosure will be described by taking an example in which the first electrode layer 301 is the anode layer and the second electrode layer 303 is the cathode layer.

The first electrode layer 301 may be electrically connected to a source 2112 or drain 2113 of a thin-film transistor, serving as the driving transistor, among the plurality of thin-film transistors 211. FIGS. 3 and 4 illustrates examples in which the first electrode layer 301 is electrically connected to the drain 2113 of the thin-film transistor 211.

As shown in FIGS. 6 to 9, the first electrode layer 301 includes first electrodes 311 belonging to the first light-emitting devices 31, second electrodes 321 belonging to the second light-emitting devices 32, and third electrodes 331 belonging to the third light-emitting devices 33.

In some embodiments, as shown in FIGS. 3 and 4, the pixel circuit stack layer 20 includes a first source-drain conductive layer 201 and a first insulating layer 202. A material of the first source-drain conductive layer 201 may include any one or more of molybdenum (Mo), magnesium (Mg), aluminum (Al), copper (Cu), or titanium (Ti).

The first insulating layer 202 is disposed between the first source-drain conductive layer 201 and the first electrode layer 301. A material of the first insulating layer 202 may include an organic insulating material or an inorganic insulating material. For example, the organic insulating material includes any one or more of: general purpose polymers of polymethyl methacrylate (PMMA) and polystyrene (PS), polymer derivatives with phenol groups, acryloyl-based polymers, imide-based polymers, aryl ether-based polymers, amide-based polymers, fluorine-based polymers, p-xylene-based polymers, or vinyl alcohol-based polymers. For example, the material of the first insulating layer 202 includes polyimide (PI).

In some other embodiments, as shown in FIG. 4, the pixel circuit stack layer 20 further includes a second source-drain conductive layer 203 and a second insulating layer 204. The second source-drain conductive layer 203 is disposed on a side of the first source-drain conductive layer 201 away from the first insulating layer 202. The second source-drain conductive layer 203 may be made of the same material as the first source-drain conductive layer 201. The second insulating layer 204 is disposed between the first source-drain conductive layer 201 and the second source-drain conductive layer 203. The second insulating layer 204 may be made of the same material as the first insulating layer 202.

As shown in FIGS. 3, 4, and 6 to 9, the first source-drain conductive layer 201 includes first connection lines 2011, second connection lines 2012, and third connection lines 2013. As shown in FIGS. 6 to 9, orthographic projections, on the substrate 10, of a first electrode 311 and a first connection line 2011 overlap; orthographic projections, on the substrate 10, of a second electrode 321 and a second connection line 2012 overlap; and orthographic projections, on the substrate 10, of a third electrode 331 and a third connection line 2013 overlap.

As shown in FIG. 3, in a case where the display panel 100 includes only the first source-drain conductive layer 201, the first connection lines 2011, the second connection lines 2012, and the third connection lines 2013 are data lines and voltage signal lines (e.g., VDD lines for transmitting VDD signals and VSS lines for transmitting VSS signals). The first source-drain conductive layer 201 further includes sources 2112 and drains 2113 of the thin-film transistors 211.

For example, the first connection lines 2011, the second connection lines 2012, and the third connection lines 2013 are all data lines. Alternatively, for example, the first connection lines 2011, the second connection lines 2012, and the third connection lines 2013 are all VDD lines. Alternatively, for example, among the first connection lines 2011, the second connection lines 2012, and the third connection lines 2013, some are data lines, and some other are VDD lines.

As shown in FIG. 4, in a case where the display panel 100 includes the first source-drain conductive layer 201 and the second source-drain conductive layer 203, the first connection lines 2011, the second connection lines 2012 and the third connection lines 2013 are a plurality of voltage signal lines. The first source-drain conductive layer 201 further includes transfer electrodes 2014. The second source-drain conductive layer 203 includes sources 2112 and drains 2113 of the thin-film transistors 211. The transfer electrode 2014 connects the anode of the light-emitting device 30 and the drain 2113 of the thin-film transistor 211.

It will be noted that, as shown in FIG. 4, in a case where the first source-drain conductive layer 201 includes the transfer electrodes 2014, no matter how the shapes of the first connection lines 2011, the second connection lines 2012 and the third connection lines 2013 change, it needs to ensure that the transfer electrodes 2014 do not overlap with the first connection lines 2011, the second connection lines 2012 and the third connection lines 2013, so as to ensure that the transfer electrodes 2014, the first connection lines 2011, the second connection lines 2012, and the third connection lines 2013 each work normally.

In the related art, a first electrode, a first connection line, and an insulating layer therebetween create a first parasitic capacitance; a second electrode, a second connection line, and the insulating layer therebetween create a second parasitic capacitance; and a third electrode, a third connection line, and the insulating layer therebetween create a third parasitic capacitance. During a process of the display panel switching from a black image to a white image, the first parasitic capacitance, the second parasitic capacitance and the third parasitic capacitance result in inconsistent turn-on speeds of the first light-emitting device, the second light-emitting device, and the third light-emitting device, which in turn leads to color cast on the display panel during the process of switching from the black image to the white image. In a case where the first light-emitting device emits light of red, the second light-emitting device emits light of blue, and the third light-emitting device emits light of green, when the first light-emitting device has the lowest turn-on speed, the display panel shows a bluish tint; when the second light-emitting device has the lowest turn-on speed, the display panel shows a yellowish tint; and when the third light-emitting device has the lowest turn-on speed, the display panel shows a purple-pink tint.

In order to solve the above technical problems, as shown in FIGS. 10 to 15, in the display panel 100 provided in some embodiments of the present disclosure, in a direction perpendicular to the substrate 10, among a distance between a first electrode 311 and a connection line whose orthographic projection on the substrate 10 overlaps with an orthographic projection of the first electrode 311 on the substrate 10, a distance between a second electrode 321 and a connection line whose orthographic projection on the substrate 10 overlaps with an orthographic projection of the second electrode 321 on the substrate 10, and a distance between a third electrode 331 and a connection line whose orthographic projection on the substrate 10 overlaps with an orthographic projection of the third electrode 331 on the substrate 10, at least two distances are not equal, so that a difference between any two of the first parasitic capacitance, the second parasitic capacitance and the third parasitic capacitance is within a preset range.

The preset range may be a range of the difference between any two of the first parasitic capacitance, the second parasitic capacitance, and the third parasitic capacitance corresponding to a degree of color cast of the display panel that is acceptable to the user.

In this way, by changing a distance between at least one electrode of the first electrode 311, the second electrode 321 and the third electrode 331 and a connection line whose orthographic projection on the substrate 10 overlaps with an orthographic projection of the at least one electrode on the substrate 10, a parasitic capacitance corresponding to the electrode may be increased or reduced, thereby adjusting a turn-on speed of a light-emitting device to which the electrode belongs. For example, for a light-emitting device with a low turn-on speed, a distance between an electrode of the light-emitting device and a connection line whose orthographic projection on the substrate overlaps with an orthographic projection of the electrode on the substrate is increased to reduce a parasitic capacitance corresponding to the electrode, thereby increasing the turn-on speed of the light-emitting device with a low turn-on speed. For another example, for a light-emitting device with a high turn-on speed, a distance between an electrode of the light-emitting device and a connection line whose orthographic projection on the substrate overlaps with an orthographic projection of the electrode on the substrate is reduced to increase a parasitic capacitance corresponding to the electrode, thereby reducing the turn-on speed of the light-emitting device with a high turn-on speed. In this way, the difference in turn-on speed among the first light-emitting device 31, the second light-emitting device 32 and the third light-emitting device 33 may be reduced, thereby ameliorating the color cast of the display panel 100 during the process of switching from the black image to the white image.

According to the formula C=εS/(4πkd) (where ε is a dielectric constant between two plates of a capacitor, C is a capacitance value of the capacitor, S is an overlapping area of the two plates, k is an electrostatic constant, and d is a distance between the two plates of the capacitor), it can be seen that the capacitance value C of the capacitor is inversely proportional to the distance d between the two plates of the capacitor. That is, the larger the distance d between the two plates of the capacitor, the smaller the capacitance value C of the capacitor.

In some embodiments, by increasing the distance between the electrode of the light-emitting device with a low turn-on speed and the connection line whose orthographic projection on the substrate overlaps with the orthographic projection of the electrode on the substrate, the parasitic capacitance corresponding to the electrode is reduced, the turn-on speed of the light-emitting device with a low turn-on speed is increased, and the difference in turn-on speed among the first light-emitting device 31, the second light-emitting device 32 and the third light-emitting device 33 is reduced, thereby ameliorating the color cast of the display panel 100 during the process of switching from the black image to the white image.

As shown in FIGS. 10 to 15, among the first electrode 311, the second electrode 321 and the third electrode 331, a distance between one electrode and a connection line whose orthographic projection on the substrate overlaps with an orthographic projection of the one electrode on the substrate is greater than a distance between each of remaining two electrodes and a connection line whose orthographic projection on the substrate overlaps with an orthographic projection of the each of remaining two electrodes on the substrate.

In this way, it is possible to reduce a parasitic capacitance corresponding to an electrode among the first electrode 311, the second electrode 321 and the third electrode 331, where a distance between the electrode and a connection line whose orthographic projection on the substrate overlaps with an orthographic projection of the electrode on the substrate is maximum, and to increase a turn-on speed of a light-emitting device to which the electrode belongs. Therefore, the difference in turn-on speed among the first light-emitting device 31, the second light-emitting device 32 and the third light-emitting device 33 is reduced, and the color cast of the display panel 100 during the process of switching from the black image to the white image is ameliorated.

In some examples, as shown in FIGS. 10 and 13, the first light-emitting device 31 is a red light-emitting device, the second light-emitting device 32 is a blue light-emitting device, and the third light-emitting device 33 is a green light-emitting device. The display panel 100 shows a bluish tint during the process of switching from the black image to the white image, indicating that the turn-on speed of the first light-emitting device 31 is lower than the turn-on speed of the second light-emitting device 32 and the turn-on speed of the third light-emitting device 33. Therefore, a distance d₁ between the first electrode 311 and the first connection line 2011 is set to be greater than a distance d₂ between the second electrode 321 and the second connection line 2012, and is set to be greater than a distance d₃ between the third electrode 331 and the third connection line 2013. In addition, the distance d₂ between the second electrode 321 and the second connection line 2012 may be greater than the distance d₃ between the third electrode 331 and the third connection line 2013, or may be equal to the distance d₃ between the third electrode 331 and the third connection line 2013, or may be less than the distance d₃ between the third electrode 331 and the third connection line 2013.

In this way, a capacitance value of the first parasitic capacitance is reduced, thereby increasing the turn-on speed of the first light-emitting device 31, and in turn ameliorating the problem that the display panel 100 shows a bluish tint during the process of switching from the black image to the white image.

In some other examples, as shown in FIGS. 11 and 14, the first light-emitting device 31 is a red light-emitting device, the second light-emitting device 32 is a blue light-emitting device, and the third light-emitting device 33 is a green light-emitting device. The display panel 100 shows a yellowish tint during the process of switching from the black image to the white image, indicating that the turn-on speed of the second light-emitting device 32 is lower than the turn-on speed of the third light-emitting device 33 and the turn-on speed of the first light-emitting device 31. Therefore, the distance d₂ between the second electrode 321 and the second connection line 2012 is set to be greater than the distance d₃ between the third electrode 331 and the third connection line 2013, and is set to be greater than the distance d₁ between the first electrode 311 and the first connection line 2011. In addition, the distance d₃ between the third electrode 331 and the third connection line 2013 may be greater than the distance d₁ between the first electrode 311 and the first connection line 2011, or may be less than the distance d₁ between the first electrode 311 and the first connection line 2011, or may be equal to the distance d₁ between the first electrode 311 and the first connection line 2011.

In this way, a capacitance value of the second parasitic capacitance is reduced, thereby increasing the turn-on speed of the second light-emitting device 32, and in turn ameliorating the problem that the display panel 100 shows a yellowish tint during the process of switching from the black image to the white image.

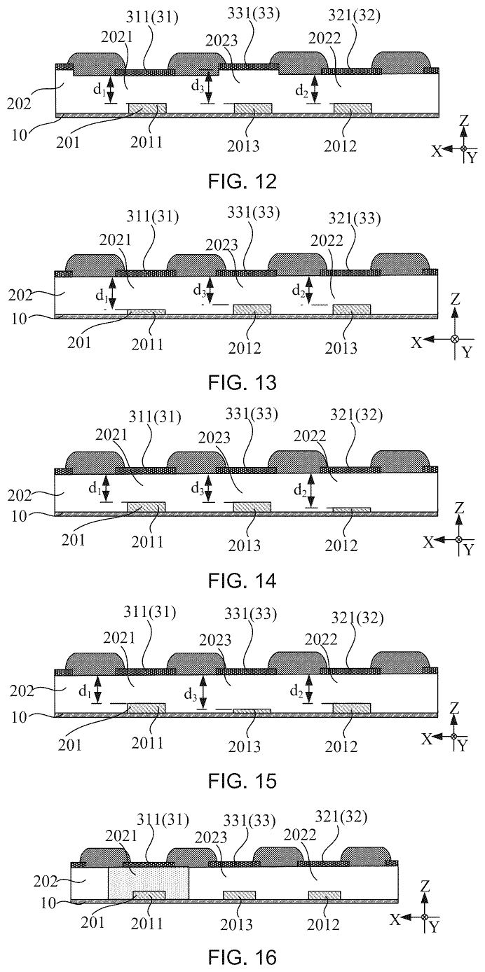

In yet some other examples, as shown in FIGS. 12 and 15, the first light-emitting device 31 is a red light-emitting device, the second light-emitting device 32 is a blue light-emitting device, and the third light-emitting device 33 is a green light-emitting device. The display panel 100 shows a purple-pink tint during the process of switching from the black image to the white image, indicating that the turn-on speed of the third light-emitting device 33 is lower than the turn-on speed of the first light-emitting device 31 and the turn-on speed of the second light-emitting device 32. Therefore, the distance d₃ between the third electrode 331 and the third connection line 2013 is set to be greater than the distance d₁ between the first electrode 311 and the first connection line 2011, and is set to be greater than the distance d₂ between the second electrode 321 and the second connection line 2012. In addition, the distance d₁ between the first electrode 311 and the first connection line 2011 may be greater than the distance d₂ between the second electrode 321 and the second connection line 2012, or may be less than the distance d₂ between the second electrode 321 and the second connection line 2012, or may be equal to the distance d₂ between the second electrode 321 and the second connection line 2012.

In this way, a capacitance value of the third parasitic capacitance is reduced, thereby increasing the turn-on speed of the third light-emitting device 33, and in turn ameliorating the problem that the display panel 100 shows a purple-pink tint during the process of switching from the black image to the white image.

In some embodiments, as shown in FIGS. 10 to 15, the first insulating layer 202 includes a first insulating portion 2021, a second insulating portion 2022, and a third insulating portion 2023. The first insulating portion 2021 is located between the first electrode 311 and the first connection line 2011, the second insulating portion 2022 is located between the second electrode 321 and the second connection line 2012, and the third insulating portion 2023 is located between the third electrode 331 and the third connection line 2013.

A thickness of one of the first insulating portion 2021, the second insulating portion 2022 and the third insulating portion 2023 is greater than thicknesses of remaining two of the first insulating portion 2021, the second insulating portion 2022 and the third insulating portion 2023.

In this way, among the first electrode 311, the second electrode 321 and the third electrode 331, a distance between one electrode and a connection line whose orthographic projection on the substrate overlaps with an orthographic projection of the one electrode on the substrate is greater than a distance between each of remaining two electrodes and a connection line whose orthographic projection on the substrate overlaps with an orthographic projection of the each of remaining two electrodes on the substrate.

In some examples, as shown in FIGS. 10 to 12, a surface, away from the substrate 10, of one of the first insulating portion 2021, the second insulating portion 2022 and the third insulating portion 2023 is higher than surfaces, away from the substrate 10, of remaining two of the first insulating portion 2021, the second insulating portion 2022 and the third insulating portion 2023. Therefore, one of a thickness of the first insulating portion 2021, a thickness of the second insulating portion 2022 and a thickness of the third insulating portion 2023 is greater than remaining two of the thickness of the first insulating portion 2021, the thickness of the second insulating portion 2022 and the thickness of the third insulating portion 2023.

For example, as shown in FIG. 10, a surface of the first insulating portion 2021 away from the substrate 10 is higher than a surface of the second insulating portion 2022 away from the substrate 10, and is higher than a surface of the third insulating portion 2023 away from the substrate 10. Therefore, the thickness of the first insulating portion 2021 is greater than the thickness of the second insulating portion 2022, and is greater than the thickness of the third insulating portion 2023. In addition, the surface of the second insulating portion 2022 away from the substrate 10 may be flush with the surface of the third insulating portion 2023 away from the substrate 10.

Alternatively, for example, as shown in FIG. 11, the surface of the second insulating portion 2022 away from the substrate 10 is higher than the surface of the first insulating portion 2021 away from the substrate 10, and is higher than the surface of the third insulating portion 2023 away from the substrate 10. Therefore, the thickness of the second insulating portion 2022 is greater than the thickness of the first insulating portion 2021, and is greater than the thickness of the third insulating portion 2023. In addition, the surface of the first insulating portion 2021 away from the substrate 10 may be flush with the surface of the third insulating portion 2023 away from the substrate 10.

Alternatively, for example, as shown in FIG. 12, the surface of the third insulating portion 2023 away from the substrate 10 is higher than the surface of the first insulating portion 2021 away from the substrate 10, and is higher than the surface of the second insulating portion 2022 away from the substrate 10. Therefore, the thickness of the third insulating portion 2023 is greater than the thickness of the first insulating portion 2021, and is greater than the thickness of the second insulating portion 2022. In addition, the surface of the first insulating portion 2021 away from the substrate 10 may be flush with the surface of the second insulating portion 2022 away from the substrate 10.

As shown in FIGS. 10 to 12, the surface, away from the substrate 10, of one of the first insulating portion 2021, the second insulating portion 2022 and the third insulating portion 2023 is higher than the surfaces, away from the substrate 10, of remaining two of the first insulating portion 2021, the second insulating portion 2022 and the third insulating portion 2023, and a thickness of the first connection line 2011, a thickness of the second connection line 2012, and a thickness of the third connection line 2013 are equal. In this case, a resistance of the first connection line 2011, a resistance of the second connection line 2012 and a resistance of the third connection line 2013 are substantially the same, so that the voltage drop of the first connection line 2011, the voltage drop of the second connection line 2012 and the voltage drop of the third connection line 2013 are substantially the same.

In some other embodiments, as shown in FIGS. 13 to 15, a thickness of one of the first connection line 2011, the second connection line 2012 and the third connection line 2013 is less than thicknesses of remaining two of the first connection line 2011, the second connection line 2012 and the third connection line 2013. Therefore, one of the thickness of the first insulating portion 2021, the thickness of the second insulating portion 2022 and the thickness of the third insulating portion 2023 is greater than remaining two of the thickness of the first insulating portion 2021, the thickness of the second insulating portion 2022 and the thickness of the third insulating portion 2023.

For example, as shown in FIG. 13, the thickness of the first connection line 2011 is less than the thickness of the second connection line 2012, and is less than the thickness of the third connection line 2013. Therefore, the thickness of the first insulating portion 2021 is greater than the thickness of the second insulating portion 2022, and is greater than the thickness of the third insulating portion 2023. In addition, the thickness of the second connection line 2012 may be equal to the thickness of the third connection line 2013.

Alternatively, for example, as shown in FIG. 14, the thickness of the second connection line 2012 is less than the thickness of the first connection line 2011, and is less than the thickness of the third connection line 2013. Therefore, the thickness of the second insulating portion 2022 is greater than the thickness of the first insulating portion 2021, and is greater than the thickness of the third insulating portion 2023. In addition, the thickness of the first connection line 2011 may be equal to the thickness of the third connection line 2013.

Alternatively, for example, as shown in FIG. 15, the thickness of the third connection line 2013 is less than the thickness of the first connection line 2011, and is less than the thickness of the second connection line 2012. Therefore, the thickness of the third insulating portion 2023 is greater than the thickness of the first insulating portion 2021, and is greater than the thickness of the second insulating portion 2022. In addition, the thickness of the first connection line 2011 may be equal to the thickness of the second connection line 2012.

As shown in FIGS. 13 to 15, the thickness of one of the first connection line 2011, the second connection line 2012 and the third connection line 2013 is less than the thicknesses of remaining two of the first connection line 2011, the second connection line 2012 and the third connection line 2013, and surfaces, away from the substrate 10, of the first insulating portion 2021, the second insulating portion 2022 and the third insulating portion 2023 are flush with each other. In this case, a surface of the first insulating layer 202 away from the substrate 10 is relatively flat, so that a uniformity of a thickness of the first electrode layer 301 is relatively high. Thus, a uniformity of a thickness of the light-emitting functional layer 302 disposed on the side of the first electrode layer 301 away from the substrate 10 is relatively high.

In some embodiments, the first insulating portion 2021, the second insulating portion 2022, and the third insulating portion 2023 are in a one-piece structure. Therefore, a dielectric constant of the first insulating portion 2021, a dielectric constant of the second insulating portion 2022, and a dielectric constant of the third insulating portion 2023 are substantially the same.

In some embodiments, as shown in FIGS. 10 to 15, among the distance d₁ between the first electrode 311 and the first connection line 2011, the distance d₂ between the second electrode 321 and the second connection line 2012, and the distance d₃ between the third electrode 331 and the third connection line 2013, one maximum distance is dₘₐₓ, and remaining two distances are dₒ₁ and dₒ₂, where dₘₐₓ/dₒ₁ is less than or equal to 1.3, and/or dₘₐₓ/dₒ₂ is less than or equal to 1.3.

For example, dₘₐₓ is in a range of 2.2 μm to 2.4 μm, for example, dₘₐₓ is 2.2 μm, 2.3 μm or 2.4 μm, which will not be described in detail in the embodiments of the present disclosure; dₒ₁ is in a range of 1.9 μm to 2.1 μm, for example, dₒ₁ is 1.9 μm, 2 μm or 2.1 μm, which will not be described in detail in the embodiments of the present disclosure; dₒ₂ is in a range of 1.9 μm to 2.1 μm, for example, dₒ₂ is 1.9 μm, 2 μm or 2.1 μm, which will not be described in detail in the embodiments of the present disclosure.

In this way, it is possible to appropriately adjust the distance between at least one electrode of the first electrode 311, the second electrode 321 or the third electrode 331 and the connection line whose orthographic projection on the substrate overlaps with the orthographic projection of the at least one electrode on the substrate, to appropriately increase or reduce the parasitic capacitance corresponding to the electrode, and in turn to appropriately adjust the turn-on speed of the light-emitting device to which the electrode belongs. For example, for the light-emitting device with a low turn-on speed, the distance between the electrode of the light-emitting device and the connection line whose orthographic projection on the substrate overlaps with the orthographic projection of the electrode on the substrate is appropriately increased to appropriately reduce the parasitic capacitance corresponding to the electrode, thereby appropriately increasing the turn-on speed of the light-emitting device with a low turn-on speed. For another example, for the light-emitting device with a high turn-on speed, the distance between the electrode of the light-emitting device and the connection line whose orthographic projection on the substrate overlaps with the orthographic projection of the electrode on the substrate is appropriately reduced to appropriately increase the parasitic capacitance corresponding to the electrode, thereby appropriately reducing the turn-on speed of the light-emitting device with a high turn-on speed.

In some examples, d₁/d₂ is less than or equal to 1.3, and/or d₁/d₃ is less than or equal to 1.3.

In this way, it is possible to ameliorate a problem that excessive increase in the distance d₁ between the first electrode 311 and the first connection line 2011 leads to excessive increase in the turn-on speed of the first light-emitting device 31, and reduce a risk of the display panel 100 appearing reddish caused by excessive increase in the turn-on speed of the first light-emitting device 31.

For example, d₁ is in a range of 2.2 μm to 2.4 μm, for example, d₁ is 2.2 μm, 2.3 μm or 2.4 μm, which will not be described in detail in the embodiments of the present disclosure; d₂ is in a range of 1.9 μm to 2.1 μm, for example, d₂ is 1.9 μm, 2 μm or 2.1 μm, which will not be described in detail in the embodiments of the present disclosure; d₃ is in a range of 1.9 μm to 2.1 μm, for example, d₃ is 1.9 μm, 2 μm or 2.1 μm, which will not be described in detail in the embodiments of the present disclosure.

In some other examples, d₂/d₁ is less than or equal to 1.3, and/or d₂/d₃ is less than or equal to 1.3.

In this way, it is possible to ameliorate a problem that excessive increase in the distance d₂ between the second electrode 321 and the second connection line 2012 leads to excessive increase in the turn-on speed of the second light-emitting device 32, and reduce a risk of the display panel 100 appearing bluish caused by excessive increase in the turn-on speed of the second light-emitting device 32.

For example, d₂ is in a range of 2.2 μm to 2.4 μm, for example, d₂ is 2.2 μm, 2.3 μm or 2.4 μm, which will not be described in detail in the embodiments of the present disclosure; d₁ is in a range of 1.9 μm to 2.1 μm, for example, d₁ is 1.9 μm, 2 μm or 2.1 μm, which will not be described in detail in the embodiments of the present disclosure; d₃ is in a range of 1.9 μm to 2.1 μm, for example, d₃ is 1.9 μm, 2 μm or 2.1 μm, which will not be described in detail in the embodiments of the present disclosure.

In some other examples, d₃/d₁ is less than or equal to 1.3, and/or d₃/d₂ is less than or equal to 1.3.

In this way, it is possible to ameliorate a problem that excessive increase in the distance d₃ between the third electrode 331 and the third connection line 2013 leads to excessive increase in the turn-on speed of the third light-emitting device 33, and reduce a risk of the display panel 100 appearing greenish caused by excessive increase in the turn-on speed of the third light-emitting device 33.

For example, d₃ is in a range of 2.2 μm to 2.4 μm, for example, d₃ is 2.2 μm, 2.3 μm or 2.4 μm, which will not be described in detail in the embodiments of the present disclosure; d₁ is in a range of 1.9 μm to 2.1 μm, for example, d₁ is 1.9 μm, 2 μm or 2.1 μm, which will not be described in detail in the embodiments of the present disclosure; d₂ is in a range of 1.9 μm to 2.1 μm, for example, d₂ is 1.9 μm, 2 μm or 2.1 μm, which will not be described in detail in the embodiments of the present disclosure.

In some embodiments, as shown in FIGS. 16 to 18, at least two of the dielectric constant ε₁ of the first insulating portion 2021, the dielectric constant ε₂ of the second insulating portion 2022, and the dielectric constant ε₃ of the third insulating portion 2023 are not equal, so that the difference between any two of the first parasitic capacitance, the second parasitic capacitance and the third parasitic capacitance is within the preset range.

In this way, by changing a dielectric constant of at least one insulating portion of the first insulating portion 2021, the second insulating portion 2022 and the third insulating portion 2023, a parasitic capacitance corresponding to the insulating portion may be increased or reduced, and a turn-on speed of a light-emitting device corresponding to the insulating portion may be adjusted. For example, for the light-emitting device with a low turn-on speed, a dielectric constant of an insulating portion between an electrode of the light-emitting device and a connection line whose orthographic projection on the substrate overlaps with an orthographic projection of the electrode on the substrate is reduced to reduce a parasitic capacitance corresponding to the electrode, thereby increasing the turn-on speed of the light-emitting device with a low turn-on speed. For another example, for the light-emitting device with a high turn-on speed, a dielectric constant of an insulating portion between an electrode of the light-emitting device and a connection line whose orthographic projection on the substrate overlaps with an orthographic projection of the electrode on the substrate is increased to increase a parasitic capacitance corresponding to the electrode, thereby reducing the turn-on speed of the light-emitting device with a high turn-on speed. In this way, the difference in turn-on speed among the first light-emitting device 31, the second light-emitting device 32 and the third light-emitting device 33 may be reduced, thereby ameliorating the color cast of the display panel 100 during the process of switching from the black image to the white image.

According to the formula C=εS/(4πkd), it can be seen that the capacitance value C of the capacitor is proportional to the dielectric constant ε between the two plates of the capacitor. That is, the smaller the dielectric constant ε between the two plates of the capacitor, the smaller the capacitance value C of the capacitor.

In some embodiments, by reducing the dielectric constant of the insulating portion between the electrode of the light-emitting device with a low turn-on speed and the connection line whose orthographic projection on the substrate overlaps with the orthographic projection of the electrode on the substrate, the parasitic capacitance corresponding to the electrode is reduced, the turn-on speed of the light-emitting device with a low turn-on speed is increased, and the difference in turn-on speed among the first light-emitting device 31, the second light-emitting device 32 and the third light-emitting device 33 is reduced, thereby ameliorating the color cast of the display panel 100 during the process of switching from the black image to the white image.

As shown in FIGS. 16 to 18, a dielectric constant of one of the first insulating portion 2021, the second insulating portion 2022, and the third insulating portion 2023 is less than dielectric constants of remaining two of the first insulating portion 2021, the second insulating portion 2022, and the third insulating portion 2023.

In this way, it is possible to reduce a parasitic capacitance corresponding to an insulating portion with the minimum dielectric constant among the first insulating portion 2021, the second insulating portion 2022 and the third insulating portion 2023, increase a turn-on speed of a light-emitting device to which an electrode corresponding to the insulating portion belongs, thereby reducing the difference in turn-on speed among the first light-emitting device 31, the second light-emitting device 32 and the third light-emitting device 33, and ameliorating the color cast of the display panel 100 during the process of switching from the black image to the white image.

In some examples, as shown in FIG. 16, the first light-emitting device 31 is a red light-emitting device, the second light-emitting device 32 is a blue light-emitting device, and the third light-emitting device 33 is a green light-emitting device. The display panel 100 shows a bluish tint during the process of switching from the black image to the white image, indicating that the turn-on speed of the first light-emitting device 31 is lower than the turn-on speed of the second light-emitting device 32 and the turn-on speed of the third light-emitting device 33. Therefore, the dielectric constant ε₁ of the first insulating portion 2021 is set to be less than the dielectric constant ε₂ of the second insulating portion 2022, and is set to be less than the dielectric constant ε₃ of the third insulating portion 2023. In addition, the dielectric constant ε₂ of the second insulating portion 2022 may be greater than the dielectric constant ε₃ of the third insulating portion 2023, or may be less than the dielectric constant ε₃ of the third insulating portion 2023, or may be equal to the dielectric constant ε₃ of the third insulating portion 2023.

In this way, the capacitance value of the first parasitic capacitance is reduced, thereby increasing the turn-on speed of the first light-emitting device 31, and in turn ameliorating the problem of the display panel 100 appearing bluish during the process of switching from the black image to the white image.

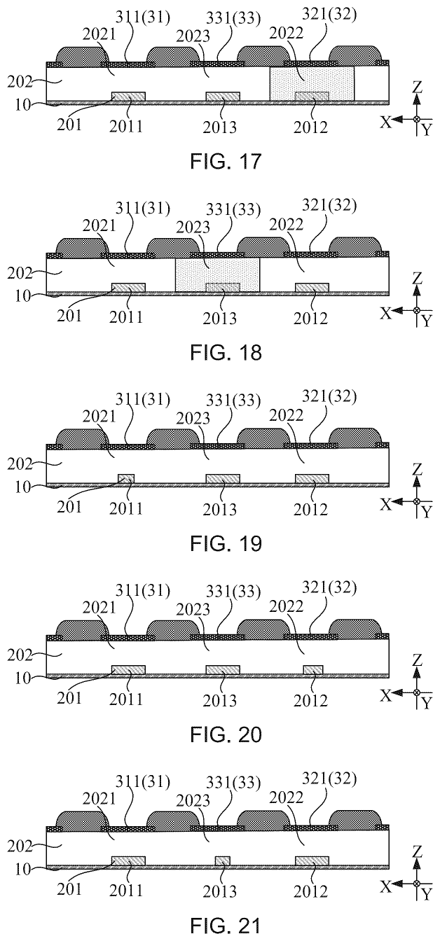

In some other examples, as shown in FIG. 17, the first light-emitting device 31 is a red light-emitting device, the second light-emitting device 32 is a blue light-emitting device, and the third light-emitting device 33 is a green light-emitting device. When the display panel 100 shows a yellowish tint during the process of switching from the black image to the white image, it indicates that the turn-on speed of the second light-emitting device 32 is lower than the turn-on speed of the first light-emitting device 31 and the turn-on speed of the third light-emitting device 33. Therefore, the dielectric constant ε₂ of the second insulating portion 2022 is set to be less than the dielectric constant ε₃ of the third insulating portion 2023, and is set to be less than the dielectric constant ε₁ of the first insulating portion 2021. In addition, the dielectric constant ε₃ of the third insulating portion 2023 may be greater than the dielectric constant ε₁ of the first insulating portion 2021, or may be less than the dielectric constant ε₁ of the first insulating portion 2021, or may be equal to the dielectric constant ε₁ of the first insulating portion 2021.

In this way, the capacitance value of the second parasitic capacitance is reduced, thereby increasing the turn-on speed of the second light-emitting device 32, and in turn ameliorating the problem of the display panel 100 appearing yellowish during the process of switching from the black image to the white image.

In some other examples, as shown in FIG. 18, the first light-emitting device 31 is a red light-emitting device, the second light-emitting device 32 is a blue light-emitting device, and the third light-emitting device 33 is a green light-emitting device. The display panel 100 shows a purple-pink tint during the process of switching from the black image to the white image, indicating that the turn-on speed of the third light-emitting device 33 is lower than the turn-on speed of the first light-emitting device 31 and the turn-on speed of the second light-emitting device 32. Therefore, the dielectric constant ε₃ of the third insulating portion 2023 is set to be less than the dielectric constant ε₁ of the first insulating portion 2021, and is set to be less than the dielectric constant ε₂ of the second insulating portion 2022. In addition, the dielectric constant ε₁ of the first insulating portion 2021 may be greater than the dielectric constant ε₂ of the second insulating portion 2022, or may be less than the dielectric constant ε₂ of the second insulating portion 2022, or may be equal to the dielectric constant ε₂ of the second insulating portion 2022.

In this way, the capacitance value of the third parasitic capacitance is reduced, thereby increasing the turn-on speed of the third light-emitting device 33, and in turn ameliorating the problem that the display panel 100 shows a purple-pink tint during the process of switching from the black image to the white image.

In some embodiments, as shown in FIGS. 16 to 18, among the first insulating portion 2021, the second insulating portion 2022 and the third insulating portion 2023, two insulating portions with relatively larger dielectric constants have the same dielectric constant, the two insulating portions with relatively larger dielectric constants are in a one-piece structure, and one insulating portion with the minimum dielectric constant is embedded in the one-piece structure formed by the two insulating portions with relatively larger dielectric constants.

In some examples, as shown in FIG. 16, the dielectric constant ε₁ of the first insulating portion 2021 is minimum, and the dielectric constant ε₂ of the second insulating portion 2022 is equal to the dielectric constant ε₃ of the third insulating portion 2023. The second insulating portion 2022 and the third insulating portion 2023 are in a one-piece structure, and the first insulating portion 2021 is embedded in the one-piece structure formed by the second insulating portion 2022 and the third insulating portion 2023.

In some other examples, as shown in FIG. 17, the dielectric constant ε₂ of the second insulating portion 2022 is minimum, and the dielectric constant ε₁ of the first insulating portion 2021 is equal to the dielectric constant ε₃ of the third insulating portion 2023. The first insulating portion 2021 and the third insulating portion 2023 are in a one-piece structure, and the second insulating portion 2022 is embedded in the one-piece structure formed by the first insulating portion 2021 and the third insulating portion 2023.

In yet some other examples, as shown in FIG. 18, the dielectric constant ε₃ of the third insulating portion 2023 is minimum, and the dielectric constant ε₂ of the second insulating portion 2022 is equal to the dielectric constant ε₁ of the first insulating portion 2021. The second insulating portion 2022 and the first insulating portion 2021 are in a one-piece structure, and the third insulating portion 2023 is embedded in the one-piece structure formed by the second insulating portion 2022 and the first insulating portion 2021.

In some embodiments, as shown in FIGS. 16 to 18, among the dielectric constant ε₁ of the first insulating portion 2021, the dielectric constant ε₂ of the second insulating portion 2022, and the dielectric constant ε₃ of the third insulating portion 2023, the minimum dielectric constant is εₘₐₓ, and remaining two dielectric constants are εₒ₁ and εₒ₂, where, εₘₐₓ/εₒ₁ is greater than or equal to 0.7, and/or εₘₐₓ/εₒ₂ is greater than or equal to 0.7.

For example, εₘₐₓ is in a range of 2.3 to 3.1, for example, εₘₐₓ is 2.3, 2.4, 2.5, 2.6, 2.7, 2.8, 2.9, 3.0 or 3.1, which will not be described in detail in the embodiments of the present disclosure; εₒ₁ is in a range of 3.2 to 3.4, for example, εₒ₁ is 3.2, 3.3 or 3.4, which will not be described in detail in the embodiments of the present disclosure; εₒ₂ is in a range of 3.2 to 3.4, for example, εₒ₂ is 3.2, 3.3 or 3.4, which will not be described in detail in the embodiments of the present disclosure.

In this way, a dielectric constant of at least one insulating portion of the first insulating portion 2021, the second insulating portion 2022 and the third insulating portion 2023 is appropriately adjusted to appropriately increase or reduce a parasitic capacitance corresponding to the insulating portion, thereby appropriately adjusting a turn-on speed of a light-emitting device to which an electrode corresponding to the insulating portion belongs. For example, for the light-emitting device with a low turn-on speed, the dielectric constant of the insulating portion between the electrode of the light-emitting device and the connection line whose orthographic projection on the substrate overlaps with the orthographic projection of the electrode on the substrate is appropriately reduced to appropriately reduce the parasitic capacitance corresponding to the electrode, thereby appropriately increasing the turn-on speed of the light-emitting device with a slow turn-on speed. For another example, for the light-emitting device with a high turn-on speed, the dielectric constant of the insulating portion between the electrode of the light-emitting device and the connection line whose orthographic projection on the substrate overlaps with the orthographic projection of the electrode on the substrate is appropriately increased to appropriately increase the parasitic capacitance corresponding to the electrode, thereby appropriately reducing the turn-on speed of the light-emitting device with a high turn-on speed.

In some examples, ε₁/ε₂ is greater than or equal to 0.7, and/or ε₁/ε₃ is greater than or equal to 0.7.

In this way, it is possible to ameliorate a problem that excessive reduction of the dielectric constant ε₁ of the first insulating portion 2021 leads to excessive increase in the turn-on speed of the first light-emitting device 31, and reduce a risk of the display panel 100 appearing reddish caused by excessive increase in the turn-on speed of the first light-emitting device 31.

For example, ε₁ is in a range of 2.3 to 3.1, for example, ε₁ is 2.3, 2.4, 2.5, 2.6, 2.7, 2.8, 2.9, 3.0 or 3.1, which will not be described in detail in the embodiments of the present disclosure; ε₂ is in a range of 3.2 to 3.4, for example, ε₂ is 3.2, 3.3 or 3.4, which will not be described in detail in the embodiments of the present disclosure; ε₃ is in a range of 3.2 to 3.4, for example, ε₃ is 3.2, 3.3 or 3.4, which will not be described in detail in the embodiments of the present disclosure.

In some other examples, ε₂/ε₁ is greater than or equal to 0.7, and/or ε₂/ε₃ is greater than or equal to 0.7.

In this way, it is possible to ameliorate a problem that excessive reduction of the dielectric constant ε₂ of the second insulating portion 2022 leads to excessive increase in the turn-on speed of the second light-emitting device 32, and reduce a risk of the display panel 100 appearing bluish caused by excessive increase in the turn-on speed of the second light-emitting device 32.

For example, ε₂ is in a range of 2.3 to 3.1, for example, ε₂ is 2.3, 2.4, 2.5, 2.6, 2.7, 2.8, 2.9, 3.0 or 3.1, which will not be described in detail in the embodiments of the present disclosure; ε₁ is in a range of 3.2 to 3.4, for example, ε₁ is 3.2, 3.3 or 3.4, which will not be described in detail in the embodiments of the present disclosure; ε₃ is in a range of 3.2 to 3.4, for example, ε₃ is 3.2, 3.3 or 3.4, which will not be described in detail in the embodiments of the present disclosure.

In yet some other examples, ε₃/ε₁ is greater than or equal to 0.7, and/or ε₃/ε₂ is greater than or equal to 0.7.

In this way, it is possible to ameliorate a problem that excessive reduction of the dielectric constant ε₃ of the third insulating portion 2023 leads to excessive increase in the turn-on speed of the third light-emitting device 33, and reduce a risk of the display panel 100 appearing greenish caused by excessive increase in the turn-on speed of the third light-emitting device 33.

For example, ε₃ is in a range of 2.3 to 3.1, for example, ε₃ is 2.3, 2.4, 2.5, 2.6, 2.7, 2.8, 2.9, 3.0 or 3.1, which will not be described in detail in the embodiments of the present disclosure; ε₁ is in a range of 3.2 to 3.4, for example, ε₁ is 3.2, 3.3 or 3.4, which will not be described in detail in the embodiments of the present disclosure; ε₂ is in a range of 3.2 to 3.4, for example, ε₂ is 3.2, 3.3 or 3.4, which will not be described in detail in the embodiments of the present disclosure.

In some embodiments, as shown in FIGS. 6 to 9 and 19 to 21, a portion of the first connection line 2011, whose orthographic projection on the substrate 10 overlaps with an orthographic projection of the first electrode 311 on the substrate 10, is a first connection segment L₁; a portion of the second connection line 2012, whose orthographic projection on the substrate 10 overlaps with an orthographic projection of the second electrode 321 on the substrate 10, is a second connection segment L₂; and a portion of the third connection line 2013, whose orthographic projection on the substrate 10 overlaps with an orthographic projection of the third electrode 331 on the substrate 10, is a third connection segment L₃.

At least two of a width of the first connection segment L₁, a width of the second connection segment L₂, and a width of the third connection segment L₃ are not equal, so that the difference between any two of the first parasitic capacitance, the second parasitic capacitance, and the third parasitic capacitance is within the preset range. The width of the first connection segment L₁ refers to a dimension of the first connection segment L₁ in a first direction X. The first direction X is perpendicular to an extending direction of the connection line (the first connection line 2011 or the second connection line 2012 or the third connection line 2013), and is perpendicular to the substrate 10.

In this way, by changing a width of at least one connection segment of the first connection segment L₁, the second connection segment L₂ and the third connection segment L₃, an overlapping area of the connection segment and an electrode whose orthographic projection on the substrate overlaps with an orthographic projection of the connection segment on the substrate may be increased or reduced, thereby increasing or reducing a parasitic capacitance corresponding to the electrode and adjusting a turn-on speed of a light-emitting device to which the electrode belongs. For example, for the light-emitting device with a low turn-on speed, an overlapping area of an electrode of the light-emitting device and a connection segment whose orthographic projection on the substrate overlaps with an orthographic projection of the electrode on the substrate is reduced to reduce a parasitic capacitance corresponding to the electrode, thereby increasing a turn-on speed of the light-emitting device with a low turn-on speed. For another example, for the light-emitting device with a high turn-on speed, an overlapping area of an electrode of the light-emitting device and a connection segment whose orthographic projection on the substrate overlaps with an orthographic projection of the electrode on the substrate is increased to increase a parasitic capacitance corresponding to the electrode, thereby reducing a turn-on speed of the light-emitting device with a high turn-on speed. In this way, the difference in turn-on speed among the first light-emitting device 31, the second light-emitting device 32 and the third light-emitting device 33 may be reduced, thereby ameliorating the color cast of the display panel 100 during the process of switching from the black image to the white image.

According to the formula C=εS/(4πkd), it can be seen that the capacitance value C of the capacitor is proportional to the overlapping area S of the two plates of the capacitor. That is, the larger the overlapping area S of the two plates of the capacitor, the larger the capacitance value C of the capacitor.

In some embodiments, by reducing the overlapping area of the electrode of the light-emitting device with a low turn-on speed and the connection segment whose orthographic projection on the substrate overlaps with the orthographic projection of the electrode on the substrate, the parasitic capacitance corresponding to the electrode is reduced, the turn-on speed of the light-emitting device with a low turn-on speed is increased, and the difference in turn-on speed among the first light-emitting device 31, the second light-emitting device 32 and the third light-emitting device 33 is reduced, thereby ameliorating the color cast of the display panel 100 during the process of switching from the black image to the white image.

As shown in FIGS. 19 to 21, one of the width of the first connection segment L₁, the width of the second connection segment L₂, and the width of the third connection segment L₃ is less than remaining two of the width of the first connection segment L₁, the width of the second connection segment L₂, and the width of the third connection segment L₃.

In this way, it is possible to reduce an overlapping area of a connection segment with the minimum width among the first connection segment L₁, the second connection segment L₂ and the third connection segment L₃ and an electrode whose orthographic projection on the substrate overlaps with an orthographic projection of the connection segment on the substrate, and to increase a turn-on speed of a light-emitting device to which the electrode belongs. Thereby, the difference in turn-on speed among the first light-emitting device 31, the second light-emitting device 32 and the third light-emitting device 33 is reduced, and the color cast of the display panel 100 during the process of switching from the black image to the white image is ameliorated.

In some examples, as shown in FIG. 19, the first light-emitting device 31 is a red light-emitting device, the second light-emitting device 32 is a blue light-emitting device, and the third light-emitting device 33 is a green light-emitting device. The display panel 100 shows a bluish tint during the process of switching from the black image to the white image, indicating that the turn-on speed of the first light-emitting device 31 is lower than the turn-on speed of the second light-emitting device 32 and the turn-on speed of the third light-emitting device 33. Therefore, the width of the first connection segment L₁ is set to be less than the width of the second connection segment L₂, and is set to be less than the width of the third connection segment L₃. In addition, the width of the second connection segment L₂ may be greater than the width of the third connection segment L₃, or may be equal to the width of the third connection segment L₃.

In this way, the capacitance value of the first parasitic capacitance is reduced, thereby increasing the turn-on speed of the first light-emitting device 31, and in turn ameliorating the problem that the display panel 100 shows a bluish tint during the process of switching from the black image to the white image.

In some other examples, as shown in FIG. 20, the first light-emitting device 31 is a red light-emitting device, the second light-emitting device 32 is a blue light-emitting device, and the third light-emitting device 33 is a green light-emitting device. The display panel 100 shows a yellowish tint during the process of switching from the black image to the white image, indicating that the turn-on speed of the second light-emitting device 32 is lower than the turn-on speed of the first light-emitting device 31 and the turn-on speed of the third light-emitting device 33. Therefore, the width of the second connection segment L₂ is set to be less than the width of the first connection segment L₁, and is set to be less than the width of the third connection segment L₃. In addition, the width of the first connection segment L₁ may be greater than the width of the third connection segment L₃, or may be equal to the width of the third connection segment L₃.

In this way, the capacitance value of the second parasitic capacitance is reduced, thereby increasing the turn-on speed of the second light-emitting device 32, and in turn ameliorating the problem that the display panel 100 shows a yellowish tint during the process of switching from the black image to the white image.

In yet some other examples, as shown in FIG. 21, the first light-emitting device 31 is a red light-emitting device, the second light-emitting device 32 is a blue light-emitting device, and the third light-emitting device 33 is a green light-emitting device. The display panel 100 shows a purple-pink tint during the process of switching from the black image to the white image, indicating that the turn-on speed of the third light-emitting device 33 is lower than the turn-on speed of the second light-emitting device 32 and the turn-on speed of the first light-emitting device 31. Therefore, the width of the third connection segment L₃ is set to be less than the width of the first connection segment L₁, and is set to be less than the width of the second connection segment L₂. In addition, the width of the first connection segment L₁ may be greater than the width of the second connection segment L₂, or may be equal to the width of the second connection segment L₂.

In this way, the capacitance value of the third parasitic capacitance is reduced, thereby increasing the turn-on speed of the third light-emitting device 33, and in turn ameliorating the problem that the display panel 100 shows a purple-pink tint during the process of switching from the black image to the white image.

In some embodiments, as shown in FIGS. 6 to 9, a portion of the first connection line 2011, whose orthographic projection on the substrate 10 does not overlap with the orthographic projection of the first electrode 311 on the substrate 10, is a fourth connection segment L₄; a portion of the second connection line 2012, whose orthographic projection on the substrate 10 does not overlap with the orthographic projection of the second electrode 321 on the substrate 10, is a fifth connection segment L₅; and a portion of the third connection line 2013, whose orthographic projection on the substrate 10 does not overlap with the orthographic projection of the third electrode 331 on the substrate 10, is a fifth connection segment L₆.

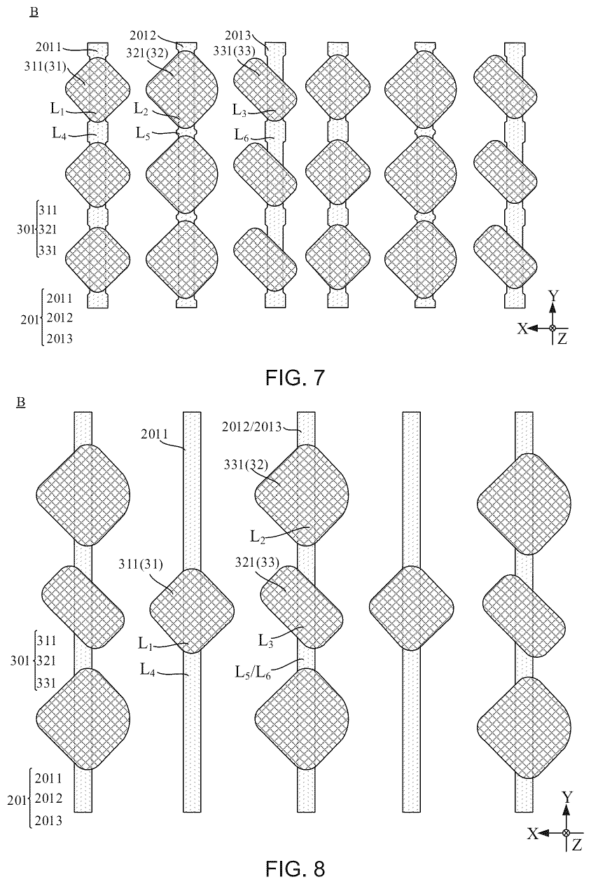

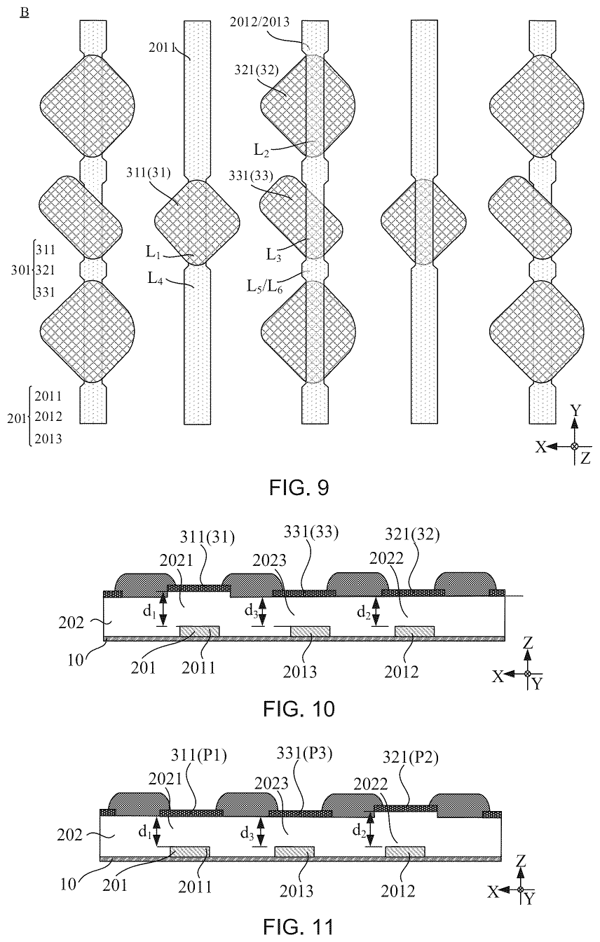

In some examples, as shown in FIGS. 7 and 9, a width of the fourth connection segment L₄ is greater than the width of the first connection segment L₁.

In this way, it is possible to reduce the resistance of the first connection line 2011, and reduce the voltage drop of the first connection line 2011.

In some other examples, as shown in FIGS. 6 and 8, the width of the fourth connection segment L₄ is equal to the width of the first connection segment L₁.

In this way, the width of the first connection line 2011 is equal everywhere, thereby reducing a risk of signal reflection on the first connection line 2011.

In some examples, as shown in FIGS. 7 and 9, a width of the fifth connection segment L₅ is greater than the width of the second connection segment L₂.

In this way, it is possible to reduce the resistance of the second connection line 2012, and reduce the voltage drop of the second connection line 2012.

In some other examples, as shown in FIGS. 6 and 8, the width of the fifth connection segment L₅ is equal to the width of the second connection segment L₂.

In this way, the width of the second connection line 2012 is equal everywhere, thereby reducing a risk of signal reflection on the second connection line 2012.

In some examples, as shown in FIGS. 7 and 9, a width of the sixth connection segment L₆ is greater than the width of the third connection segment L₃.

In this way, it is possible to reduce the resistance of the third connection line 2013, thereby reducing the voltage drop of the third connection line 2013.

In some other examples, as shown in FIGS. 6 and 8, the width of the sixth connection segment L₆ is equal to the width of the third connection segment L₃.

In this way, the width of the third connection line 2013 is equal everywhere, thereby reducing signal reflection on the third connection line 2013.

The arrangement of the first light-emitting devices 31, the second light-emitting devices 32 and the third light-emitting devices 33 will be described below.

In some embodiments, as shown in FIGS. 6 and 7, a plurality of first light-emitting devices 31, a plurality of second light-emitting devices 32 and a plurality of third light-emitting devices 33 are arranged in a plurality of rows in the first direction X, and are arranged in a plurality of columns in a second direction Y. Light-emitting devices in each row are cyclically arranged in the first direction X in an order of a first light-emitting device 31, a second light-emitting device 32 and a third light-emitting device 33. Each column of light-emitting devices includes: first light-emitting devices 31, second light-emitting devices 32, or third light-emitting devices 33, which are arranged in the second direction Y.

In this case, the first connection line 2011, the second connection line 2012 and the third connection line 2013 are different connection lines.

In some other embodiments, as shown in FIGS. 8 and 9, a plurality of first light-emitting devices 31, a plurality of second light-emitting devices 32 and a plurality of third light-emitting devices 33 are arranged in a plurality of rows in the first direction X, and are arranged in a plurality of columns in the second direction Y. Each row of light-emitting devices includes first light-emitting devices 31 and third light-emitting devices 33 arranged alternately in the first direction X, or each row of light-emitting devices includes second light-emitting devices 32 arranged in the first direction X. A light-emitting device row consisting of first light-emitting devices 31 and third light-emitting devices 33 and a light-emitting device row consisting of second light-emitting devices 32 are arranged alternately. Each column of light-emitting devices includes second light-emitting devices 32 and third light-emitting devices 33 alternately arranged in the second direction Y, or each column of light-emitting devices includes first light-emitting devices 31 arranged in the second direction Y. A light-emitting device column consisting of second light-emitting devices 32 and third light-emitting devices 33 and a light-emitting device column consisting of first light-emitting devices 31 are alternately arranged.

In this case, the second connection line 2012 is also used as the third connection line 2013, and the second connection segment L₂ and the third connection segment L₃ are different portions of the second connection line 2012.

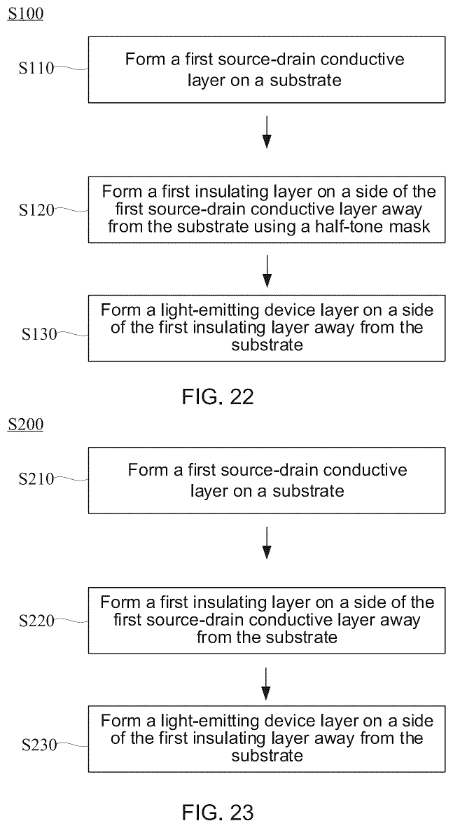

The embodiments of the present disclosure further provide a method S100 for manufacturing a display panel 100, and the method S100 is used for manufacturing the display panel 100 described in any one of the above embodiments. As shown in FIG. 22, the method S100 includes S110 to S130.

In S110, a first source-drain conductive layer 201 is formed on a substrate 10.

The first source-drain conductive layer 201 includes first connection lines 2011, second connection lines 2012 and third connection lines 2013.

In S120, a first insulating layer 202 is formed on a side of the first source-drain conductive layer 201 away from the substrate 10 using a half-tone mask.

In S130, a light-emitting device layer 30 is formed on a side of the first insulating layer 202 away from the substrate 10.

The light-emitting device layer 30 includes a first electrode layer 301, a light-emitting functional layer 302 and a second electrode layer 303 that are sequentially stacked in a direction away from the substrate 10. The light-emitting device layer 30 forms first light-emitting devices 31, second light-emitting devices 32, and third light-emitting devices 33, which emit light of different colors. The first electrode layer 301 includes first electrodes 311 belonging to the first light-emitting devices 31, second electrodes 321 belonging to the second light-emitting devices 32, and third electrodes 331 belonging to the third light-emitting devices 33. Orthographic projections, on the substrate 10, of a first electrode 311 and a first connection line 2011 overlap; orthographic projections, on the substrate 10, of a second electrode 321 and a second connection line 2012 overlap; and orthographic projections, on the substrate 10, of a third electrode 331 and a third connection line 2013 overlap.

In the display panel obtained by the above method, at least two of a thickness of a portion of the first insulating layer 202 located between the first electrode 311 and the first connection line 2011, a thickness of a portion of the first insulating layer 202 located between the second electrode 321 and the second connection line 2012, and a thickness of a portion of the first insulating layer 202 located between the third electrode 331 and the third connection line 2013 are not equal. Therefore, a difference between any two of a parasitic capacitance created by the first electrode 311 and the first connection line 2011, a parasitic capacitance created by the second electrode 321 and the second connection line 2012, and a parasitic capacitance created by the third electrode 331 and the third connection line 2013 is within a preset range. As a result, the difference in turn-on speed among the first light-emitting device 31, the second light-emitting device 32 and the third light-emitting device 33 is reduced, and a problem of color cast of the display panel 100 during a process of switching from a black image to a white image is ameliorated.

The embodiments of the present disclosure further provide a method S200 for manufacturing a display panel 100, and the method S200 is used for manufacturing the display panel 100 described in any one of the above embodiments. As shown in FIG. 23, the method S200 includes S210 to S230.

In S210, a first source-drain conductive layer 201 is formed on a substrate 10.

The first source-drain conductive layer 201 includes first connection lines 2011, second connection lines 2012 and third connection lines 2013.

In S220, a first insulating layer 202 is formed on a side of the first source-drain conductive layer 201 away from the substrate 10.

The first insulating layer 202 includes first insulating portions 2021, second insulating portions 2022, and third insulating portions 2023.

In S230, a light-emitting device layer 30 is formed on a side of the first insulating layer 202 away from the substrate 10.

The light-emitting device layer 30 includes a first electrode layer 301, a light-emitting functional layer 302 and a second electrode layer 303 that are sequentially stacked in a direction away from the substrate 10. The light-emitting device layer 30 forms first light-emitting devices 31, second light-emitting devices 32, and third light-emitting devices 33, which emit light of different colors. The first electrode layer 301 includes first electrodes 311 belonging to the first light-emitting devices 31, second electrodes 321 belonging to the second light-emitting devices 32, and third electrodes 331 belonging to the third light-emitting devices 33. Orthographic projections, on the substrate 10, of a first electrode 311 and a first connection line 2011 overlap; orthographic projections, on the substrate 10, of a second electrode 321 and a second connection line 2012 overlap; and orthographic projections, on the substrate 10, of a third electrode 331 and a third connection line 2013 overlap.

In the display panel obtained by the above method, a first insulating portion 2021 is disposed between the first electrode 311 and the first connection line 2011, a second insulating portion 2022 is disposed between the second electrode 321 and the second connection line 2012, and a third insulating portion 2023 is disposed between the third electrode 331 and the third connection line 2013. At least two of a dielectric constant ε₁ of the first insulating portion 2021, a dielectric constant ε₂ of the second insulating portion 2022, and a dielectric constant ε₃ of the third insulating portion 2023 are not equal. Therefore, a difference between any two of a parasitic capacitance created by the first electrode 311 and the first connection line 2011, a parasitic capacitance created by the second electrode 321 and the second connection line 2012, and a parasitic capacitance created by the third electrode 331 and the third connection line 2013 is within a preset range. As a result, the difference in turn-on speed among the first light-emitting device 31, the second light-emitting device 32 and the third light-emitting device 33 is reduced, and a problem of color cast of the display panel 100 during a process of switching from a black image to a white image is ameliorated.

In the description of the specification, specific features, structures, materials or characteristics may be combined in a suitable manner in any one or more embodiments or examples.

The foregoing descriptions are merely specific implementations of the present disclosure, but the protection scope of the present disclosure is not limited thereto. Any changes or replacements that a person skilled in the art could conceive of within the technical scope of the present disclosure shall be included in the protection scope of the present disclosure. Therefore, the protection scope of the present disclosure should be determined by the protection scope of the claims.

What is claimed is:

1. A display panel, comprising:
a substrate;
a first source-drain conductive layer located on a side of the substrate, the first source-drain conductive layer including first connection lines, second connection lines and third connection lines;
a first insulating layer located on a side of the first source-drain conductive layer away from the substrate; and
a light-emitting device layer located on a side of the first insulating layer away from the substrate, wherein the light-emitting device layer includes a first electrode layer, a light-emitting functional layer, and a second electrode layer that are sequentially stacked in a direction away from the substrate; the light-emitting device layer forms first light-emitting devices, second light-emitting devices, and third light-emitting devices, which emit light of different colors; the first electrode layer includes first electrodes belonging to the first light-emitting devices, second electrodes belonging to the second light-emitting devices, and third electrodes belonging to the third light-emitting devices; orthographic projections, on the substrate, of a first electrode and a first connection line overlap; orthographic projections, on the substrate, of a second electrode and a second connection line overlap; orthographic projections, on the substrate, of a third electrode and a third connection line overlap;
wherein in a direction perpendicular to the substrate, at least two of a distance between the first electrode and the first connection line, a distance between the second electrode and the second connection line, and a distance between the third electrode and the third connection line are not equal, so that a difference between any two of a parasitic capacitance created by the first electrode and the first connection line, a parasitic capacitance created by the second electrode and the second connection line, and a parasitic capacitance created by the third electrode and the third connection line is within a preset range.

2. The display panel according to claim 1, wherein a distance between one electrode, among the first electrode, the second electrode and the third electrode, and a connection line whose orthographic projection on the substrate overlaps with an orthographic projection of the one electrode on the substrate is greater than a distance between each of remaining two electrodes, among the first electrode, the second electrode and the third electrode, and a connection line whose orthographic projection on the substrate overlaps with an orthographic projection of the each of remaining two electrodes on the substrate.

3. The display panel according to claim 2, wherein the first insulating layer includes a first insulating portion, a second insulating portion, and a third insulating portion; the first insulating portion is disposed between the first electrode and the first connection line, the second insulating portion is disposed between the second electrode and the second connection line, and the third insulating portion is disposed between the third electrode and the third connection line; wherein one of a thickness of the first insulating portion, a thickness of the second insulating portion and a thickness of the third insulating portion is greater than remaining two of the thickness of the first insulating portion, the thickness of the second insulating portion and the thickness of the third insulating portion.

4. The display panel according to claim 3, wherein a surface, away from the substrate, of one of the first insulating portion, the second insulating portion and the third insulating portion is higher than surfaces, away from the substrate, of remaining two of the first insulating portion, the second insulating portion and the third insulating portion.

5. The display panel according to claim 4, wherein a thickness of the first connection line, a thickness of the second connection line, and a thickness of the third connection line are equal.

6. The display panel according to claim 3, wherein a thickness of one of the first connection line, the second connection line and the third connection line is less than thicknesses of remaining two of the first connection line, the second connection line and the third connection line.

7. The display panel according to claim 6, wherein surfaces, away from the substrate, of the first insulating portion, the second insulating portion and the third insulating portion are flush with each other.

8. The display panel according to claim 3, wherein the first insulating portion, the second insulating portion and the third insulating portion are in a one-piece structure.

9. The display panel according to claim 2, wherein among the distance between the first electrode and the first connection line, the distance between the second electrode and the second connection line, and the distance between the third electrode and the third connection line, a maximum distance is dₘₐₓ, and remaining two distances are dₒ₁ and dₒ₂;
wherein dₘₐₓ/dₒ₁ is less than or equal to 1.3, and/or dₘₐₓ/dₒ₂ is less than or equal to 1.3.

10. A display panel, comprising:
a substrate;
a first source-drain conductive layer located on a side of the substrate, the first source-drain conductive layer including first connection lines, second connection lines and third connection lines;
a light-emitting device layer located on a side of the first source-drain conductive layer away from the substrate, wherein the light-emitting device layer includes a first electrode layer, a light-emitting functional layer, and a second electrode layer that are sequentially stacked in a direction away from the substrate; the light-emitting device layer forms first light-emitting devices, second light-emitting devices, and third light-emitting devices, which emit light of different colors; the first electrode layer includes first electrodes belonging to the first light-emitting devices, second electrodes belonging to the second light-emitting devices, and third electrodes belonging to the third light-emitting devices; orthographic projections, on the substrate, of a first electrode and a first connection line overlap; orthographic projections, on the substrate, of a second electrode and a second connection line overlap; orthographic projections, on the substrate, of a third electrode and a third connection line overlap; and
a first insulating layer located between the first source-drain conductive layer and the first electrode layer, wherein the first insulating layer includes a first insulating portion, a second insulating portion, and a third insulating portion; the first insulating portion is disposed between the first electrode and the first connection line, the second insulating portion is disposed between the second electrode and the second connection line, and the third insulating portion is disposed between the third electrode and the third connection line;
wherein at least two of a dielectric constant of the first insulating portion, a dielectric constant of the second insulating portion and a dielectric constant of the third insulating portion are not equal, so that a difference between any two of a parasitic capacitance created by the first electrode and the first connection line, a parasitic capacitance created by the second electrode and the second connection line, and a parasitic capacitance created by the third electrode and the third connection line is within a preset range.

11. The display panel according to claim 10, wherein one of the dielectric constant of the first insulating portion, the dielectric constant of the second insulating portion and the dielectric constant of the third insulating portion is less than remaining two of the dielectric constant of the first insulating portion, the dielectric constant of the second insulating portion and the dielectric constant of the third insulating portion.

12. The display panel according to claim 11, wherein dielectric constants of two insulating portions with relatively larger dielectric constants among the first insulating portion, the second insulating portion and the third insulating portion are the same, and the two insulating portions with relatively larger dielectric constants are in a one-piece structure; and one insulating portion with a minimum dielectric constant among the first insulating portion, the second insulating portion and the third insulating portion is embedded in the one-piece structure formed by the two insulating portions with relatively larger dielectric constants.

13. The display panel according to claim 11, wherein among the dielectric constant of the first insulating portion, the dielectric constant of the second insulating portion and the dielectric constant of the third insulating portion, a minimum dielectric constant is εₘₐₓ, and remaining two dielectric constants are εₒ₁ and εₒ₂;
wherein εₘₐₓ/εₒ₁ is greater than or equal to 0.7, and/or εₘₐₓ/εₒ₂ is greater than or equal to 0.7.

14. A display panel, comprising:
a substrate;
a first source-drain conductive layer located on a side of the substrate, the first source-drain conductive layer including first connection lines, second connection lines and third connection lines;
a first insulating layer located on a side of the first source-drain conductive layer away from the substrate; and
a light-emitting device layer located on a side of the first insulating layer away from the substrate, wherein the light-emitting device layer includes a first electrode layer, a light-emitting functional layer, and a second electrode layer that are sequentially stacked in a direction away from the substrate; the light-emitting device layer forms a plurality of first light-emitting devices, a plurality of second light-emitting devices, and a plurality of third light-emitting devices, which emit light of different colors; the first electrode layer includes first electrodes belonging to the plurality of first light-emitting devices, second electrodes belonging to the plurality of second light-emitting devices, and third electrodes belonging to the plurality of third light-emitting devices; orthographic projections, on the substrate, of a first electrode and a first connection segment of a first connection line overlap; orthographic projections, on the substrate, of a second electrode and a second connection segment of a second connection line overlap; orthographic projections, on the substrate, of a third electrode and a third connection segment of a third connection line overlap;
wherein at least two of a width of the first connection segment, a width of the second connection segment, and a width of the third connection segment are not equal, so that a difference between any two of a parasitic capacitance created by the first electrode and the first connection line, a parasitic capacitance created by the second electrode and the second connection line, and a parasitic capacitance created by the third electrode and the third connection line is within a preset range.

15. The display panel according to claim 14, wherein one of the width of the first connection segment, the width of the second connection segment, and the width of the third connection segment is less than remaining two of the width of the first connection segment, the width of the second connection segment, and the width of the third connection segment.

16. The display panel according to claim 14, wherein a portion of the first connection line, whose orthographic projection on the substrate does not overlap with an orthographic projection of the first electrode on the substrate, is a fourth connection segment; a portion of the second connection line, whose orthographic projection on the substrate does not overlap with an orthographic projection of the second electrode on the substrate, is a fifth connection segment; a portion of the third connection line, whose orthographic projection on the substrate does not overlap with an orthographic projection of the third electrode on the substrate, is a sixth connection segment;
wherein a width of the fourth connection segment is greater than the width of the first connection segment; and/or a width of the fifth connection segment is greater than the width of the second connection segment; and/or a width of the sixth connection segment is greater than the width of the third connection segment.

17. The display panel according to claim 14, wherein the plurality of first light-emitting devices, the plurality of second light-emitting devices, and the plurality of third light-emitting devices are arranged in a plurality of rows in a first direction, and are arranged in a plurality of columns in a second direction; each row of light-emitting devices includes first light-emitting devices and third light-emitting devices arranged alternately in the first direction, or each row of light-emitting devices includes second light-emitting devices arranged in the first direction; a light-emitting device row consisting of first light-emitting devices and third light-emitting devices and a light-emitting device row consisting of second light-emitting devices are arranged alternately; each column of light-emitting devices includes second light-emitting devices and third light-emitting devices arranged alternately in the second direction, or each column of light-emitting devices includes first light-emitting devices arranged in the second direction; a light-emitting device column consisting of second light-emitting devices and third light-emitting devices and a light-emitting device column consisting of first light-emitting devices are arranged alternately;
wherein the second connection line is also used as the third connection line, and the second connection segment and the third connection segment are different portions of the second connection line.

18. A display apparatus, comprising the display panel according to claim 1.

19.-20. (canceled)

21. A display apparatus, comprising the display panel according to claim 10.

22. A display apparatus, comprising the display panel according to claim 14.
